(19) United States
(12) Patent Application Publication
(10) Pub. No.: US 2024/0313166 A1
(43) Pub. Date: Sep. 19, 2024

(54) LIGHT-EMITTING ELEMENT, DISPLAY DEVICE INCLUDING THE SAME AND METHOD OF FABRICATING THE SAME

(71) Applicant: Samsung Display Co., LTD., Yongin-si (KR)

(72) Inventors: Hyung Rae CHA, Yongin-si (KR); Jun Youn KIM, Yongin-si (KR); Dong Uk KIM, Yongin-si (KR); Myeong Hee KIM, Yongin-si (KR); Seul Ki KIM, Yongin-si (KR); Hee Keun LEE, Yongin-si (KR)

(73) Assignee: Samsung Display Co., LTD., Yongin-si (KR)

(21) Appl. No.: 18/597,759

(22) Filed: Mar. 6, 2024

(30) Foreign Application Priority Data
Mar. 15, 2023 (KR) 10-2023-0033612

(51) Int. Cl. H01L 33/40; H01L 25/16; H01L 33/20

(52) U.S. Cl. CPC H01L 33/405; H01L 25/167; H01L 33/20; H01L 2933/0016

(57) ABSTRACT

A light emitting element, a display device including the same and a method of fabricating the same. The light emitting element may include an element rod including a first semiconductor layer, an active layer, and a second semiconductor layer. First and second contact electrodes may be respectively disposed on a first end surface and a second and opposite end surface of the element rod. A reflection layer may surround the first contact electrode and the element rod. An inner insulating layer may be disposed inside the reflection layer and surround the first contact electrode and the element rod. An outer insulating layer external to the reflection layer and may surround the first contact electrode and the element rod. A first inclination of side surfaces of the first semiconductor layer and the active layer and a second inclination of a side surface of the second semiconductor layer may be different.

### CROSS-REFERENCE TO RELATED APPLICATIONS

This application claims priority under 35 U.S.C. 119 from Korean Patent Application No. 10-2023-0033612 filed on Mar. 15, 2023 in the Korean Intellectual Property Office, the entire contents of which are incorporated herein by reference.

### BACKGROUND

### 1. Technical Field

The disclosure relates to a light emitting element, a display device including the same and a method of fabricating the same.

### 2. Description of the Related Art

As the information society develops, the demand for a display device for displaying an image may be increasing in various forms. The display device may be a flat panel display, such as a liquid crystal display device, a field emission display device, or a light emitting display panel.

The light emitting display device may include an organic light emitting display device including an organic light emitting diode element as a light emitting element, an inorganic light emitting display device including an inorganic semiconductor element as a light emitting element, or a micro light emitting display device including an ultra-small light emitting diode element (or micro light emitting diode element) as a light emitting element.

### SUMMARY

Aspects and features of embodiments of the disclosure provide a method of a display device minimizing damage of an active layer during etching by first etching a first semiconductor layer for light emitting element and the active layer and second etching a second semiconductor layer after protecting side surfaces of the first semiconductor layer and the active layer with an insulating layer, and a light emitting element and a display device using the same.

However, embodiments of the disclosure may not be limited to those set forth herein. The above and other embodiments of the disclosure will become more apparent to one of ordinary skill in the art to which the disclosure pertains by referencing the detailed description of the disclosure given below.

According to an embodiment, a light emitting element may include an element rod including a first semiconductor layer, an active layer, and a second semiconductor layer, first and second contact electrodes respectively disposed on a first end surface and a second end surface facing the first end surface of the element rod, a reflection layer surrounding the first contact electrode and the element rod, an inner insulating layer disposed inside the reflection layer and surrounding the first contact electrode and the element rod and an outer insulating layer disposed external to the reflection layer and surrounding the first contact electrode and the element rod, wherein a first inclination of side surfaces of the first semiconductor layer and the active layer and a second inclination of side surface of the second semiconductor layer may be different.

The second inclination may be an angle between a reference surface and a side surface of the second semiconductor layer, the first inclination may be an angle between the reference surface and side surfaces of the first semiconductor layer and the active layer, and the reference surface may be a surface parallel to contact surfaces of the second contact electrode and the second semiconductor layer.

The second inclination may be smaller than the first inclination.

A width of the second semiconductor layer may be wider towards the second contact electrode.

The light emitting element may further include a common electrode disposed on the second contact electrode.

The inner insulating layer may include a first insulating layer surrounding a side surfaces of the first contact electrode, and the side surfaces of the first semiconductor layer and the active layer, and a second insulating layer surrounding a side surface of the first insulating layer and the side surface of the second semiconductor layer, the outer insulating layer may include a third insulating layer surrounding a side surface and a first surface of the reflection layer, the third insulating layer defines a first opening exposing the first surface of the reflection layer, and the light emitting element may also include a connection electrode disposed in the first opening.

The reflection layer may include a first reflection layer disposed on the second insulating layer, the first reflection layer surrounding the side surfaces of the first semiconductor layer, the active layer and the second semiconductor layer and a second reflection layer disposed on the first contact electrode, the second reflection layer covering a first surface of the first semiconductor layer.

The second reflection layer may extend from the first reflection layer.

The second reflection layer may be spaced apart from the first reflection layer, and the outer insulating layer may be further disposed between the second reflection layer and the first reflection layer.

The light emitting element may also include a fourth insulating layer disposed on the second semiconductor layer, the fourth insulating layer defining a second opening exposing the second semiconductor layer. The second contact electrode may be disposed in the second opening.

According to an embodiment, a display device may include a semiconductor circuit substrate including a pixel circuit portion, a light emitting element disposed on the pixel circuit portion, a connection electrode disposed between the light emitting element and the pixel circuit portion and a common electrode disposed on the light emitting element, wherein the light emitting element may include an element rod including a first semiconductor layer, an active layer, and a second semiconductor layer, first and second contact electrodes respectively disposed on a first end surface and the second and opposite end surface of the element rod, a first insulating layer surrounding side surfaces of the first contact electrode, the first semiconductor layer and the active layer, a second insulating layer may surround a side surface of the first insulating layer and a side surface of the second semiconductor layer, a reflection layer surrounding a side surface of the second insulating layer and a first surface of the first contact electrode, and a third insulating layer surrounding a side surface and a first surface of the reflection layer. A first inclination of the side surfaces of the first semiconductor layer and the active layer and a second inclination of the side surface of the second semiconductor layer may be different.

The second inclination may be an angle between a reference surface and the side surface of the second semiconductor layer, the first inclination may be an angle between the reference surface and the side surfaces of the first semiconductor layer and the active layer, wherein the reference surface may be parallel to a contact surface of the second contact electrode and a contact surface of the second semiconductor layer, and wherein the second inclination may be smaller than the first inclination.

A width of the second semiconductor layer may be wider towards a second contact electrode.

The third insulating layer may include a first opening exposing the first surface of the reflection layer, the connection electrode may be disposed in the first opening, the light emitting element may also include a fourth insulating layer disposed between the second semiconductor layer and the common electrode, the fourth insulating layer may define a second opening exposing the second semiconductor layer, and the second contact electrode may be disposed on the second opening.

The reflection layer may include a first reflection layer disposed on the second insulating layer, the first reflection layer may surround the side surfaces of the first semiconductor layer, the active layer and the second semiconductor layer and a second reflection layer disposed on the first contact layer, the second reflection layer may overlap a first surface of the first semiconductor layer.

The second reflection layer may extend from the first reflection layer.

The second reflection layer may be spaced apart from the first reflection layer, and the third insulating layer may be disposed between the second reflection layer and the first reflection layer.

The display device may also include a fourth insulating layer disposed between the second semiconductor layer and the common electrode, the fourth insulating layer defining a second opening exposing the second semiconductor layer, wherein the second contact electrode may be disposed in the second opening.

According to an embodiment, a method of fabricating a display device may include forming a first semiconductor material layer, a second semiconductor material layer, an active material layer, a third semiconductor material layer, a first contact electrode layer, and a hard mask layer on a growth substrate, forming a first element rod, a first contact electrode, and a hard mask by etching the active material layer, the third semiconductor material layer, the first contact electrode layer, and the hard mask layer using a photoresist mask in a first etching process, forming a first insulating layer covering the first element rod, the first contact electrode, and the hard mask, forming a second element rod by etching the second semiconductor material layer using the hard mask in a second etching process, forming a second insulating layer, a reflection layer, and a third insulating layer on side surfaces of the first contact electrode, the first element rod, and the second element rod formed by the first etching process and the second etching process, forming a connection electrode on the first contact electrode, disposing the growth substrate on a semiconductor circuit substrate having a pixel electrode formed thereon, bonding the connection electrode to the pixel electrode, removing the growth substrate and the first semiconductor material layer, forming a second contact electrode and a fourth insulating layer on the second semiconductor material layer; and forming a common electrode on the second contact electrode, wherein a first inclination of side surfaces of the first semiconductor layer and the active layer and a second inclination of a side surface of the second semiconductor layer may be different.

The forming of the second insulating layer, the reflection layer, and the third insulating layer may include forming the second insulating layer surrounding the side surfaces of the first contact electrode, the first element rod and the second element rod formed by the first etching process and the second etching process, forming the reflection layer on the second insulating layer, the reflection layer covering side surfaces of the first contact electrode, the first element rod, and the second element rod and the first surface of the first contact electrode, forming the third insulating layer on the reflection layer, the third insulating layer being disposed on the side surfaces of the first contact electrode, the first element rod, and the second element rod and the first surface of the first contact electrode, the third insulating layer having an opening, and forming the connection electrode on a portion of the first contact electrode exposed by the opening.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating a display device according to an embodiment;

FIG. 2 is a plan view illustrating a display device according to an embodiment;

FIG. 3 is a plan view illustrating pixels of a display panel according to an embodiment;

FIG. 4 is a schematic cross-sectional view illustrating an example of a display panel taken along line A-A′ of FIG. 3;

FIG. 5 is an enlarged view of a light emitting element of FIG. 4 according to an embodiment;

FIG. 6 is an enlarged view of a light emitting element of FIG. 4 according to an embodiment;

FIGS. 7A to 7F are enlarged views of light emitting elements of FIG. 4 according to an embodiments;

FIG. 8 is a flowchart illustrating a method of manufacturing a display device according to an embodiment;

FIGS. 9 to 27 are schematic cross-sectional views method of manufacturing a display device according to an embodiment;

FIG. 28 is a perspective view of a smart device including a display device according to the embodiment of FIG. 1;

FIG. 29 is a perspective view of a virtual reality (VR) device a display device according to an embodiment of the disclosure;

FIG. 30 is a perspective view of a dashboard and a center console of an automobile including display devices according to an embodiment of the disclosure;

FIG. 31 is a transparent display device including a display device according to an embodiment of the disclosure;

FIG. 32 is a perspective view of a display device according to an embodiment of the disclosure; and

FIG. 33 is a perspective view of a smart device including the display device of FIG. 32.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in an embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be predisposed differently from the described order. For example, two consecutively described processes may be predisposed substantially at a same time or predisposed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” “directly disposed,” or “directly coupled to” another element or layer, there are no intervening elements or layers present. In case that an element is “directly placed” on another element, it means that an element is in “contact” with the other element. In the specification, “component A is directly disposed on component B” means that an adhesive layer may not be disposed between component A and component B. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. Further, the X-axis, the Y-axis, and the Z-axis may not be limited to three axes of a rectangular coordinate system, such as the x, y, and z axes, and may be interpreted in a broader sense. For example, the X-axis, the Y-axis, and the Z-axis may be perpendicular to one another, or may be different directions that may not be perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items. A description that a component is “configured to” perform a specified operation may be defined as a case where the component is constructed and arranged with structural features that can cause the component to perform the specified operation.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, may not be necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be disposed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, portion, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein. Hereinafter, embodiments of the disclosure will be described in detail with reference to the accompanying drawings.

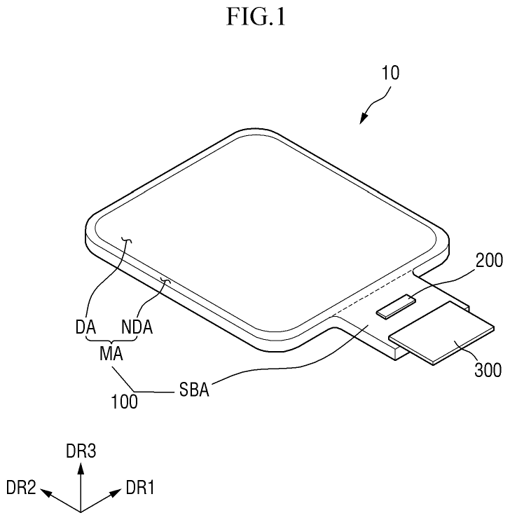

FIG. 1 is a perspective view illustrating a display device according to an embodiment.

Referring to FIG. 1, a display device 10 may be a device for displaying a moving image or a still image. The display device may be used as a display screen of various products such as televisions, laptop computers, monitors, billboards and the Internet of Things (IoT) as well as portable electronic devices such as mobile phones, smart phones, tablet personal computer (tablet PC), smart watches, watch phones, mobile communication terminals, electronic notebooks, electronic books, portable multimedia players (PMPs), navigation systems and ultra mobile PCs (UMPCs).

The display device 10 may be a light emitting display device such as an organic light emitting display device using an organic light emitting diode, a quantum dot light emitting display including a quantum dot light emitting layer, an inorganic light emitting display device including an inorganic semiconductor, and a micro light emitting display device using a micro or nano light emitting diode (micro LED or nano LED). Hereinafter, the display device 10 has been described as a micro light emitting display device, but the disclosure may be not limited thereto. In the following description, micro or nano light emitting diodes (micro LEDs or nano LEDs) may be referred to as micro light emitting diodes for the sake of simplicity.

The display device 10 includes a display panel 100, a display driving circuit 200 and a circuit board 300.

The display panel 100 may be formed in a rectangular plane having shorter sides in a first direction DR1 and longer sides in a second direction DR2 intersecting the first direction DR1. Each of the corners where the short side in the first direction DR1 meets the longer side in the second direction DR2 may be rounded with a predetermined curvature or may be a right angle. The shape of the display panel 100 in case that viewed from the top may not be limited to a quadrangular shape, but may be formed in a different polygonal shape, a circular shape, or an elliptical shape. The display panel 100 may be formed flat, but may not be limited thereto. For example, the display panel 100 may be formed at left and right ends, and may include a curved portion having a constant curvature or a varying curvature. In addition, the display panel 100 may be flexible so that it can be curved, bent, folded or rolled.

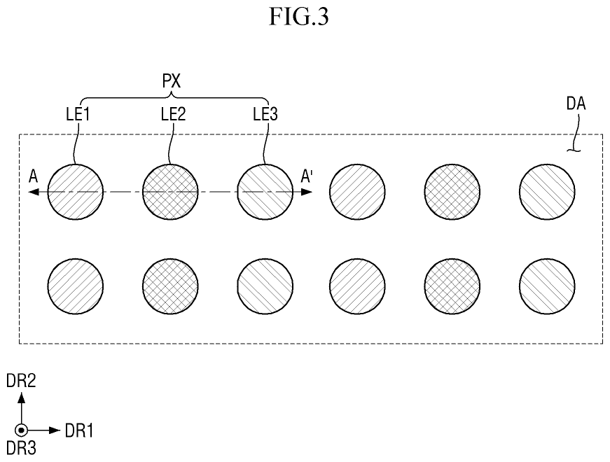

A substrate SUB1 of the display panel 100 may include a main region MA and a sub-region SBA. The main region MA may include a display area DA where images may be displayed, and a non-display area NDA may surround the display area DA. The display area DA may include multiple sub-pixels PX for displaying images (see FIG. 3). The pixels PX may be provided in the display area DA of the display panel 100. Each pixel PX may be provided in plural, each pixel PX corresponding to a minimum portion for displaying an image. The pixels PX may emit white light and/or color light. The pixels PX may emit any one color light among red, green, and blue, but the disclosure may not be limited thereto, and may instead emit other colors such as cyan, magenta, and yellow.

The sub-region SBA may protrude from one side of the main region MA in the second direction DR2. Although it may be shown in FIG. 1 that the sub-region SBA may be unfolded, the sub-region SBA may be bent and, arranged on the bottom surface of the display panel 100. In the case where the sub-region SBA may be bent, it may overlap the main region MA in a third direction DR3 which may be the thickness direction of the display panel 100. The display driving circuit 200 may be arranged in the sub-region SBA.

The display driving circuit 200 may generate signals and voltages for driving the display panel 100. The display driving circuit 200 may be an integrated circuit (IC) and be attached onto the display panel 100 by a chip on glass (COG) technique, a chip on plastic (COP) technique, or an ultrasonic bonding technique, but the disclosure may not be limited thereto. For example, the display driving circuit 200 may instead be attached onto the circuit board 300 by a chip on film (COF) technique.

The circuit board 300 may be attached to one end of the sub-region SBA of the display panel 100. Thus, the circuit board 300 may be electrically connected to the display panel 100 and the display driving circuit 200. The display panel 100 and the display driving circuit 200 may receive digital video data, timing signals, and driving voltages through the circuit board 300. The circuit board 300 may be a flexible printed circuit board, a printed circuit board, or a flexible film such as a chip on film.

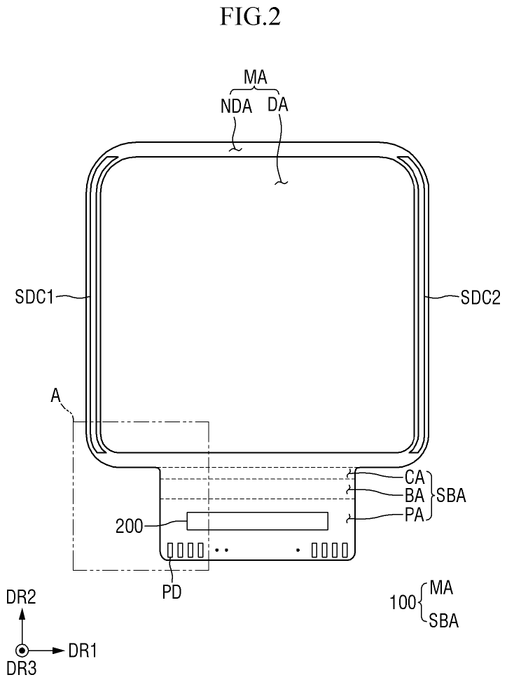

FIG. 2 is a plan view illustrating a display device according to an embodiment. Referring to FIG. 2, the display panel 100 may include a main region MA and a sub-region SBA. The main region MA may include a display area DA displaying an image and a non-display area NDA that may be disposed at a peripheral area of the display area DA. The display area DA may occupy most of the main region MA and be disposed at the center of the main region MA.

The non-display area NDA may be disposed adjacent to the display area DA. The non-display area NDA may be an area outside the display area DA. The non-display area NDA may be disposed to surround the display area DA. The non-display area NDA may be an edge area of the display panel 100.

A first scan driver SDC1 and a second scan driver SDC2 may be disposed in the non-display area NDA. The first scan driver SDC1 may be disposed at a side (for example, left side) of the display panel 100, and the second scan driver SDC2 may be disposed at another side (for example, right side) of the display panel 100, but the disclosure may not be limited thereto. Each of the first scan driver SDC1 and the second scan driver SDC2 may be electrically connected to the display driving circuit 200 via scan fan-out lines. Each of the first scan driver SDC1 and the second scan driver SDC2 may receive scan control signals from the display driving circuit 200, generate scan signals in response to the scan control signals, and output the generated scan signals to scan lines.

The sub-region SBA may protrude from one side of the main region MA in the second direction DR2. The length of the sub-region SBA in the second direction DR2 may be less than a length of the main region MA in the second direction DR2. The length of the sub-region SBA in the first direction DR1 may be substantially equal to or less than a length of the main region MA in the first direction DR1. The sub-region SBA may be foldable to be disposed under the display panel 100 to overlap the main region MA in a third direction DR3.

The sub-region SBA may include a connection area CA, a pad area PA, and a bending area BA. The connection area CA may be an area protruding from one side of the main region MA in the second direction DR2. A side of the connection area CA may be in contact with the non-display area NDA, and another side of the connection area CA may be in contact with the bending area BA.

The pad area PA may be an area on which pads PD and the display driving circuit 200 may be disposed. The display driving circuit 200 may be attached to driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA may be an area that may be bent. In case that the bending area BA is bent, the pad area PA may be disposed under the connection area CA and the main region MA. The bending area BA may be disposed between the connection area CA and the pad area PA. A side of the bending area BA may be in contact with the connection area CA and another side of the bending area BA may be in contact with the pad area PA.

FIG. 3 is a plan view illustrating pixels of a display panel according to an embodiment. Referring to FIG. 3, each of the pixels PX may include first to third light emitting elements LE1, LE2, and LE3 that emit light. In an embodiment of the specification, each of the pixels PX includes three light emitting elements LE1 through LE3, but embodiments of the specification may not be limited thereto. In addition, although each of the first to third light emitting elements LE1, LE2, and LE3 has a circular planar shape, embodiments of the specification may not be limited thereto.

The first light emitting element LE1 may emit first light. The first light may be light in a blue wavelength band. For example, a main peak wavelength (B-peak) of the first light may be located at about 370 nm to about 460 nm, but embodiments of the specification may not be limited thereto.

The second light emitting element LE2 may emit second light. The second light may be light in a green wavelength band. For example, a main peak wavelength (G-peak) of the second light may be located at about 480 nm to about 560 nm, but embodiments of the specification may not be limited thereto.

The third light emitting element LE3 may emit the first light. The first light may be light in the blue wavelength band. For example, the main peak wavelength (B-peak) of the first light may be located at about 370 nm to about 460 nm, but embodiments of the specification may not be limited thereto. In the current embodiment, the third light emitting element LE3 may emit the first light, but the first light emitted from the third light emitting element LE3 may be converted into third light by a wavelength conversion layer and/or a color filter which will be described later. The third light may be light in a red wavelength band of about 600 nm to about 750 nm.

The first light emitting elements LE1, the second light emitting elements LE2, and the third light emitting elements LE3 may be alternately arranged in the first direction DR1. For example, the first light emitting elements LE1, the second light emitting elements LE2, and the third light emitting elements LE3 may be arranged in the order of the first light emitting element LE1, the second light emitting element LE2, and the third light emitting element LE3 in the first direction DR1. The first light emitting elements LE1 may be arranged in the second direction DR2. The second light emitting elements LE2 may be arranged in the second direction DR2. The third light emitting elements LE3 may be arranged in the second direction DR2.

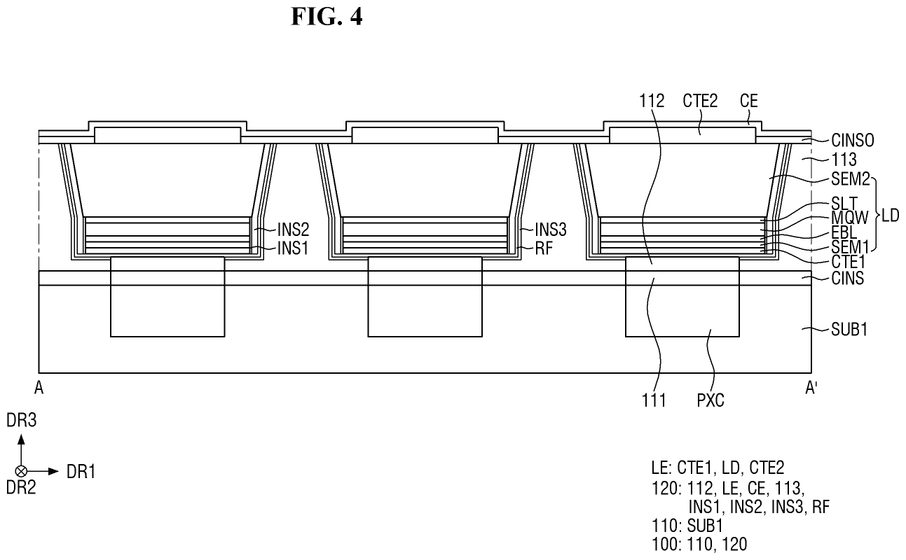

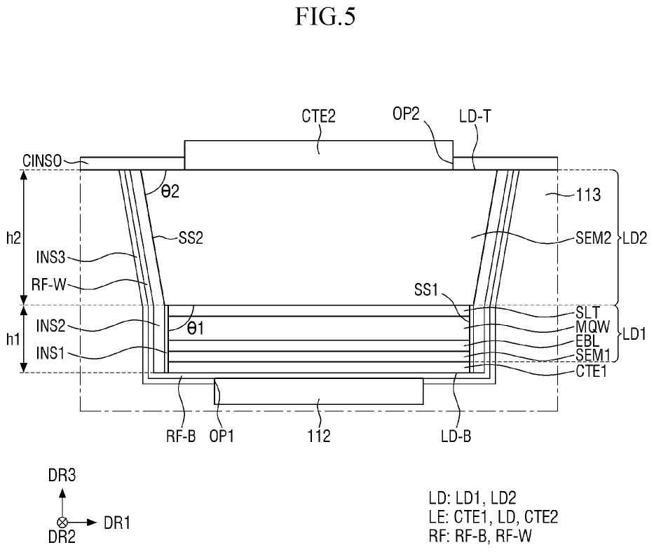

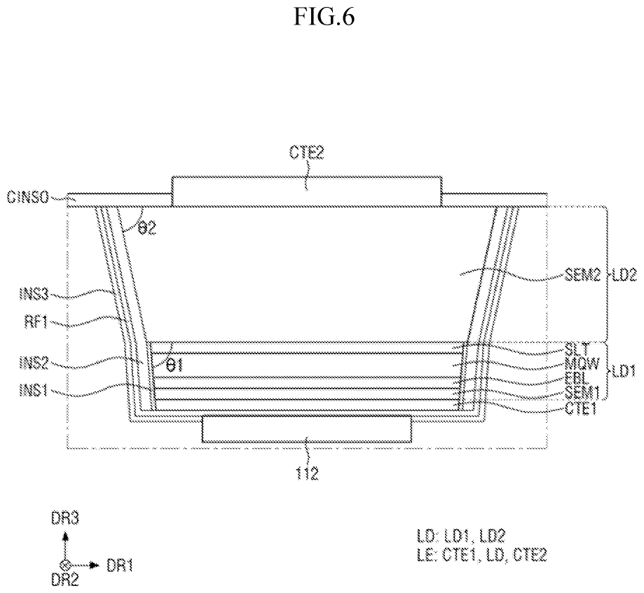

FIG. 4 is a schematic cross-sectional view illustrating an example of a display panel taken along line A-A′ of FIG. 3, FIG. 5 is an enlarged view of a light emitting element of FIG. 4 according to an embodiment, and FIG. 6 is an enlarged view of a light emitting element of FIG. 4 according to an embodiment. Referring to FIG. 4, the display panel 100 may include a semiconductor circuit board 110 and a light emitting element layer 120. The semiconductor circuit board 110 may include multiple pixel circuit portions PXC, pixel electrodes 111, and a circuit insulating layer CINS.

The semiconductor circuit board 110 may be a silicon wafer substrate formed using a semiconductor process and may be a first substrate. The pixel circuit portions PXC of the semiconductor circuit board 110 may be formed using a semiconductor process. The pixel circuit portions PXC may be disposed in the display area DA and the non-display area NDA. Each of the pixel circuit portions PXC may be electrically connected to a corresponding pixel electrode 111. For example, the pixel circuit portions PXC and the pixel electrodes 111 may be electrically connected with a one-to-one correspondence to each other. The pixel circuit portions PXC may respectively overlap light emitting elements LE in the third direction DR3.

Each of the pixel circuit portions PXC may include at least one transistor formed using a semiconductor process. In addition, each of the pixel circuit portions PXC may further include at least one capacitor formed using a semiconductor process. The pixel circuit portions PXC may include, for example, a complementary metal oxide semiconductor (CMOS) circuit. Each of the pixel circuit portions PXC may apply a pixel voltage or an anode voltage to a corresponding pixel electrode 111.

The circuit insulating layer CINS may be disposed on a semiconductor circuit substrate SUB1. The circuit insulating layer CINS may expose each of the pixel electrodes 111 so that the pixel electrodes 111 may be electrically connected to the light emitting element layer 120. The circuit insulating layer CINS may protect the pixel circuit portions PXC and may planarize a step formed by the pixel electrode 111 disposed on the pixel circuit portions PXC. The circuit insulating layer CINS may include an inorganic insulating material such as silicon oxide (SiOₓ), silicon nitride(SiNₓ), silicon oxynitride (SiOₓN_{y}), aluminum oxide (SiOₓN_{y}), aluminum nitride (AlN), or a combination thereof.

Each of the pixel electrodes 111 may be disposed on a corresponding pixel circuit portion PXC. Each of the pixel electrodes 111 may be an exposed electrode exposed from the pixel circuit portion PXC. Each of the pixel electrodes 111 and the pixel circuit portion PXC may be integral with each other. Each of the pixel electrodes 111 may receive a pixel voltage or an anode voltage from the pixel circuit portion PXC. The pixel electrodes 111 may include a metal material such as aluminum (Al).

The light emitting element layer 120 may be disposed on the semiconductor circuit substrate SUB1. The light emitting element layer 120 may include connection electrodes 112, light emitting elements LE, and a common electrode CE. In addition, the light emitting element layer 120 may include multiple insulating layers INS1, INS2, and INS3, a reflection layer RF, and a planarization layer 113.

The connection electrodes 112 may be disposed on the corresponding pixel electrodes 111, respectively. The connection electrodes 112 may include a metal material for bonding to the pixel electrodes 111 and the light emitting elements LE. For example, the connection electrodes 112 may include at least any one of gold (Au), copper (Cu), aluminum (Al), and tin (Sn). As another example, the connection electrodes 112 may include a first layer including any one of gold (Au), copper (Cu), aluminum (Al) and tin (Sn) and a second layer including another one of gold (Au), copper (Cu), aluminum (Al) tin (Sn), or a combination thereof.

The light emitting elements LE may be disposed on the connection electrode 112. The light emitting elements LE may be vertical light emitting diode elements extending long in the third direction DR3. For example, a length of each light emitting element LE in the third direction DR3 may be less than a length in the horizontal direction. The length in the horizontal direction indicates a length in the first direction DR1 or a length in the second direction DR2. For example, the length of each light emitting element LE in the third direction DR3 may be about 1 μm to about 5 μm, but may be not limited thereto.

Each of the light emitting elements LE may be shaped like a cylinder, a disk, or a rod whose width may be greater than its height. However, the disclosure may not be limited thereto, and each of the light emitting elements LE may instead have various other shapes including shapes such as a rod, a wire and a tube, polygonal prisms such as a cube, a rectangular parallelepiped and a hexagonal prism, and a shape extending in a direction and having a partially inclined outer surface.

The light emitting elements LE may be micro light emitting diode elements. Each of the light emitting elements LE may include a first contact electrode CTE1, a first semiconductor layer SEM1, an electron blocking layer EBL, an active layer MQW, a superlattice layer SLT, a second semiconductor layer SEM2, and a second contact electrode CTE2 in the third direction DR3. The first semiconductor layer SEM1, the electron blocking layer EBL, the active layer MQW, the superlattice layer SLT, the second semiconductor layer SEM2, and a second contact electrode CTE2 may be sequentially stacked on each other on the semiconductor circuit substrate SUB1 in the third direction DR3. Here, the first semiconductor layer SEM1, the electron blocking layer EBL, the active layer MQW, the superlattice layer SLT, and the second semiconductor layer SEM2 may be referred to as an element rod LD. The first contact electrode CTE1 and the second contact electrode CTE2 may be disposed on both ends of the element rod LD, respectively.

The first contact electrode CTE1 may be disposed on the connection electrode 112. The first contact electrode CTE1 may serve to apply a light emitting signal to the light emitting element LE by contacting the connection electrode 112. The light emitting element LE may include at least one first contact electrode CTE1. In FIG. 5, it may be illustrated that the light emitting element LE includes one first contact electrode CTE1, but the disclosure may not be limited thereto. In some cases, the light emitting element LE may include a larger number of first contact electrodes CTE1 or may omit them. A description of the light emitting element LE to be described later may be equally applied even if the number of first contact electrodes CTE1 may be different or a different structure is further included.

The first contact electrode CTE1 may include a conductive metal. For example, the first contact electrode CTE1 may include at least any one of gold (Au), copper (Cu), tin (Sn), titanium (Ti), aluminum (Al), and silver (Ag). The second contact electrode CTE2 may be disposed on the light emitting element LE. The second contact electrode CTE2 may be made of a Transparent Conductive Oxide (TCO), such as indium tin oxide (ITO) and/or indium zinc oxide (IZO) that can transmit light.

The element rod LD may include a first element rod LD1 and a second element rod LD2. The first element rod LD1 may be disposed on the first contact electrode CTE1. A height h1 of the first element rod LD1 may be in the range of, but may not be limited to, about 0.4 μm to about 0.6 μm.

The first element rod LD1 may include a first sidewall SS1 having a first taper angle θ1. The first taper angle θ1 of the first sidewall SS1 may be about 90 degrees as shown in FIG. 5 and may be greater than or equal to about 70 degrees and less than about 90 degrees as shown in FIG. 6. Therefore, the first sidewall SS1 of the first element rod LD1 may be formed with a regular taper.

The first element rod LD1 may include a first semiconductor layer SEM1, an electron blocking layer EBL, an active layer MQW, and a superlattice layer SLT. The first semiconductor layer SEM1, the electron blocking layer EBL, the active layer MQW, and the superlattice layer SLT may be sequentially stacked on the first contact electrode CTE1 in the third direction DR3.

In one embodiment, the first semiconductor layer SEM1 may be disposed on the first contact electrode CTE1. The first semiconductor layer SEM1 may be a p-type semiconductor and may include a semiconductor material having a chemical formula of AlₓGa_{y}In_{1-x-y}N (0≤x≤1, 0≤y≤1, 0≤x+y≤1). For example, the first semiconductor layer SEM1 may be any one or more of p-type doped AlGaInN, GaN, AlGaN, InGaN, AlN, and InN. The first semiconductor layer SEM1 may be doped with a p-type dopant, and the p-type dopant may be Mg, Zn, Ca, Se, Ba, the like, or a combination thereof. For example, the first semiconductor layer SEM1 may be p-GaN doped with p-type Mg as the dopant. The thickness of the first semiconductor layer SEM1 may be in the range of, but may not be limited to, about 30 nm to about 200 nm.

The electron blocking layer EBL may be disposed on the first semiconductor layer SEM1. The electron blocking layer EBL may be a layer for inhibiting or preventing too many electrons from flowing into the active layer MQW. For example, the electron blocking layer EBL may be p-AlGaN doped with p-type Mg. A thickness of the electron blocking layer EBL may be in the range of, but not limited to, about 10 nm to about 50 nm. In addition, the electron blocking layer EBL may instead be omitted.

The active layer MQW may be disposed on the electron blocking layer EBL. The active layer MQW may emit light through combination of electron-hole pairs according to an electrical signal received though the first semiconductor layer SEM1 and the second semiconductor layer SEM2. The active layer MQW may emit first light that may be light in the blue wavelength band, or second light that may be light in the green wavelength band.

The active layer MQW may include a material having a single or multiple quantum well structure. In case that the active layer MQW includes a material having a multiple quantum well structure, it may have a structure in which multiple well layers and multiple barrier layers may be alternately stacked on each other. Here, the well layers may be formed of InGaN, and the barrier layers may be formed of GaN or AlGaN, but the disclosure may not be limited thereto. The thickness of the well layer may be about 1 nm to about 4 nm, and the thickness of the barrier layer may be about 3 nm to about 10 nm.

In an embodiment, the active layer MQW may have a structure in which a semiconductor material having a large band gap and a semiconductor material having a small band gap may be alternately stacked on each other or may include different Group III to Group V semiconductor materials depending on the wavelength band of light that it emits. Light emitted from the active layer MQW may not be limited to the first light. In some cases, the second light (light in the green wavelength band) or the third light (light in the red wavelength band) may be emitted. In an embodiment, in case that indium is included among the semiconductor materials included in the active layer MQW, the color of light emitted may vary according to the indium content. For example, light in the blue wavelength band may be emitted if the indium content may be about 15%, light in the green wavelength band may be emitted if the indium content may be about 25%, and light in the red wavelength band may be emitted if the indium content may be about 35% or more.

The superlattice layer SLT may be disposed on the active layer MQW. The superlattice layer SLT may be a layer for relieving stress between the second semiconductor layer SEM2 and the active layer MQW. For example, the superlattice layer SLT may be made of InGaN and/or GaN. A thickness of the superlattice layer SLT may be about 50 nm to about 200 nm. The superlattice layer SLT may instead be omitted.

The second element rod LD2 may be disposed on the first element rod LD1. The height h2 of the second element rod LD2 may be in the range of, but may not be limited to, about 0.8 μm to about 1.2 μm. A ratio of the height h1 of the first element rod LD1 to the height h2 of the second element rod LD2 may be about 1:2. For example, the height h2 of the second element rod LD2 may be about twice the height h1 of the first element rod LD1.

The second element rod LD2 may include a second sidewall SS2 having a second taper angle θ2. The second taper angle θ2 of the second sidewall SS2 may be about 60 degrees to about 80 degrees. In addition, the second taper angle θ2 may be smaller than the first taper angle θ1. Therefore, the second sidewall SS2 may be formed with a regular taper. The width of the second element rod LD2 becomes wider toward the second contact electrode CTE2.

The second element rod LD2 may include the second semiconductor layer SEM2. The second semiconductor layer SEM2 may be disposed on the superlattice layer SLT. The second semiconductor layer SEM2 may be an n-type semiconductor. The second semiconductor layer SEM2 may include a semiconductor material having a chemical formula of AlₓGa_{y}In_{1-x-y}N (0≤x≤1, 0≤y≤1, 0≤x+y≤1). For example, the second semiconductor layer SEM2 may be any one or more of n-type doped AlGaInN, GaN, AlGaN, InGaN, AlN, and InN. The second semiconductor layer SEM2 may be doped with an n-type dopant, and the n-type dopant may be Si, Ge, Sn, the like, or a combination thereof. For example, the second semiconductor layer SEM2 may be n-GaN doped with n-type Si as the dopant. A thickness of the second semiconductor layer SEM2 may be in the range of, but not limited to, about 0.8 μm to about 1.2 μm.

The insulating layers INS1, INS2, and INS3 and a reflection layer RF1 may be disposed on the side of the element rod LD. The insulating layers INS1, INS2, and INS3 may include a first insulating layer INS1, a second insulating layer INS2, and a third insulating layer INS3. The first insulating layer INS1 may be disposed to surround the first sidewall SS1 of the first element rod LD1. The first insulating layer INS1 may not be disposed on the second sidewall SS2 corresponding to the second element rod LD2. The first insulating layer INS1 may reduce leakage current by adopting a ZAZ (ZrO₂/Al₂O₃/ZrO₂) composite stack structure, but the disclosure may not be limited thereto.

The second insulating layer INS2 serves as a diffusion barrier and prevents a p-n junction of the element rod from being short-circuited. To this end, the second insulating layer INS2 may surround the second sidewall SS2 of the second element rod LD2 as well as the first sidewall SS1 of the first element rod LD1 on the first insulating layer INS1. The second insulating layer INS2 may be made of an inorganic layer such as a silicon oxide layer (SiO₂), an aluminum oxide layer (Al₂O₃), a hafnium oxide layer (HfOₓ), or a combination thereof.

The third insulating layer INS3 may be disposed to surround the second insulating layer INS2. Before describing the third insulating layer INS3, the reflection layer RF disposed between the second insulating layer INS2 will first be described.

The reflection layer RF may include a sidewall reflector RF-W disposed on the second insulating layer INS2 to surround the first sidewall SS1 of the first element rod LD1 and the second sidewall SS2 of the second element rod LD2, and a bottom reflector RF-B disposed on first end surface LD-B of the element rod LD. The bottom reflector RF-B may extend from the sidewall reflector RF-W to cover first end surface LD-B of the element rod LD. For example, the reflection layer RF may cover all regions of the element rod LD except for the second end surface LD-T facing the first end surface LD-B. Accordingly, the reflection layer RF allows the light emitted from the element rod LD to be emitted upward. Specifically, since the second taper angle θ2 of the second element rod LD2 disposed above the first element rod LD1 may be smaller than the first taper angle θ1 of the first element rod LD1, light condensing efficiency to the upper portion may be improved. The reflection layer RF may adopt omni-directional reflectors (hereinafter, referred to as ODR), but may not be limited thereto. The omni-directional reflector means a reflector that maintains high reflectivity with respect to a wide wavelength range and a wide range of incident angle. The reflection layer RF may have a reflectance of about 90% or more within a visible range and may have a thickness of about 5 nm or more.

As an insulating layer for protecting the reflection layer RF, the third insulating layer INS3 may be disposed on the first sidewall SS1 of the first element rod LD1 and the second sidewall SS2 of the second element rod LD2 and on the reflection layer RF. In addition, the third insulating layer INS3 may be disposed on first end surface LD-B of the first element rod LD1. The third insulating layer INS3 may include a first opening OP1 at first end surface LD-B of the first element rod LD1. The reflection layer RF may be exposed through the first opening OP1 in the third insulating layer INS3. The connection electrode 112 may be in contact with the reflection layer RF exposed by the first opening OP1 of the third insulating layer INS3. The third insulating layer INS3 may be formed of aluminum oxide (Al₂O₃), but may not be limited thereto.

In one embodiment of the disclosure, two insulating layers inside the reflection layer RF may be illustrated as an example, but the disclosure may not be limited thereto, and multiple insulating layers may be formed. However, the total thickness of the insulating layers inside the reflection layer RF may be about 100 nm or less. Each of the multi-layer insulation layer may include any one of ZrO₂, HfO₂, Al₂O₃, SiO₂, Y₂O₃, Ta₂O₅, La₂O₃, AlN, BeO, Nb₂O₅, TiO₂, CeO₂, MgO, Sr₂O₃, AlGaN, InGaN, SiNₓ, AlOₓN_{y}, HfN, ZrN, HfOₓN_{y}, ZrOₓN_{y}, or a combination thereof.

In addition, a single insulating layer may be formed outside the reflection layer RF. A thickness of the insulating layer disposed outside the reflection layer RF may be about 40 nm or less.

The planarization layer 113 may be disposed between each light emitting element LE. The planarization layer 113 may be a layer for planarizing a step formed by each light emitting element LE. The planarization layer 113 may be made of an organic layer such as acryl resin, epoxy resin, phenolic resin, polyamide resin, polyimide resin, or a combination thereof.

An element insulating layer (or fourth insulating layer) CINS0 may be disposed on the planarization layer 113 and on the light emitting elements LE. The element insulating layer CINS0 may expose each light emitting element LE so that each light emitting element LE may be electrically connected to the common electrode CE. The element insulating layer CINS0 may protect the light emitting elements LE and may include a second opening OP2 overlapping the second end surface LD-T of the light emitting element LE. The diameter of the second opening OP2 may be greater than the diameter of the first opening OP1, but may not be limited thereto. In the element insulating layer CINS0, the second semiconductor layer SEM2 of the light emitting element LE may be exposed by the second opening OP2. The second contact electrode CTE2 may be disposed on the second semiconductor layer SEM2 exposed by the second opening OP2 of the element insulating layer CINS0.

The second contact electrode CTE2 may be in contact with the common electrode CE. The common electrode CE may be disposed on upper surfaces of the light emitting elements LE and on the upper surface of the planarization layer 113. The common electrode CE may be a common layer commonly formed across the pixels. The common electrode CE may be made of a Transparent Conductive Oxide (TCO), such as indium tin oxide (ITO) and/or indium zinc oxide (IZO) that can transmit light.

Although not illustrated in an embodiment of the disclosure, an optical wavelength conversion layer for converting a wavelength of light, a color filter for transmitting only light of a specific wavelength, and the like may be further disposed on each light emitting element LE.

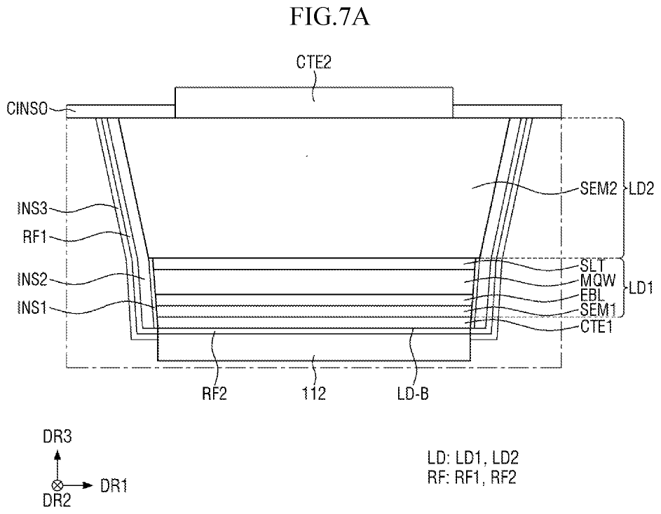

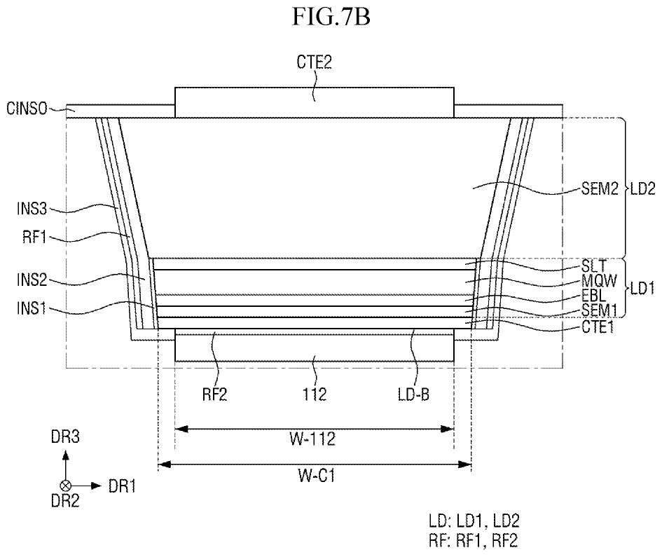

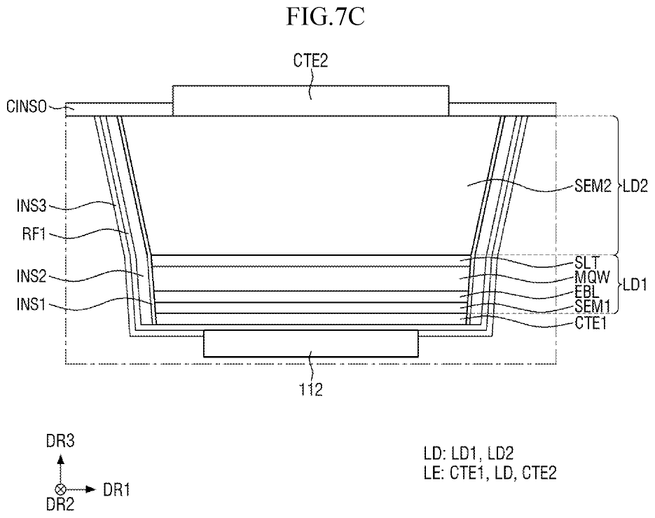

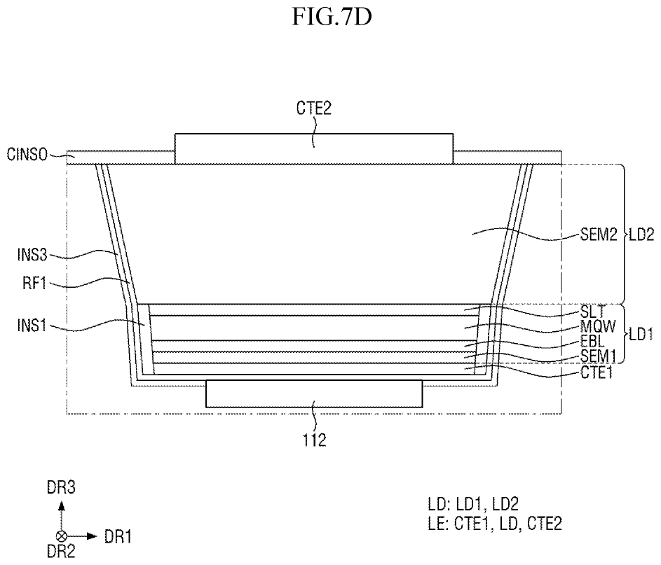

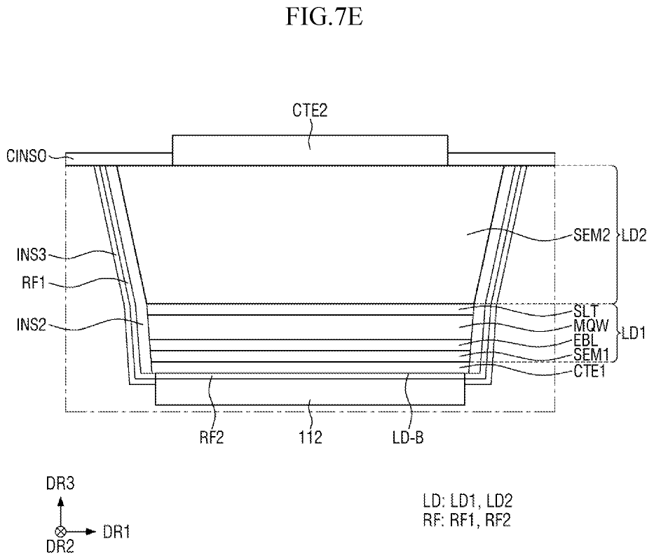

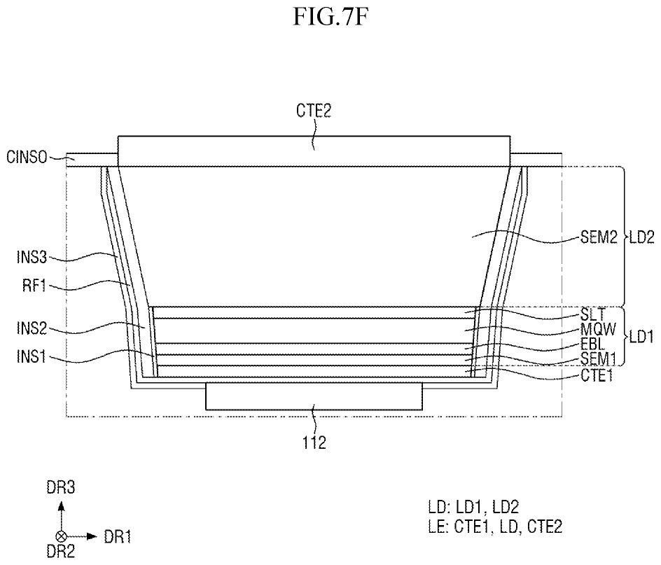

FIGS. 7A to 7F are enlarged views of light emitting elements of FIG. 4 according to other embodiments. Since any one or more of the first insulating layer INS1, the second insulating layer INS2, the reflection layer RF, the third insulating layer INS3, the connection electrode 112 and the second contact electrode CTE2 may be different in FIGS. 7A to 7F, different components will be described.

Referring to FIG. 7A, the reflection layer RF may include a first reflection layer RF1 and a second reflection layer RF2. The first reflection layer RF1 surrounds side surfaces of the first element rod LD1 and the second element rod LD2, and the second reflection layer RF2 may be disposed on first end surface LD-B of the first element rod LD1. The second reflection layer RF2 may be disposed between a first contact electrode CTE1 and a connection electrode 112.

The second reflection layer RF2 may be disposed in the first opening OP1 disposed in the third insulating layer INS3 and on the first contact electrode CTE1. Accordingly, the first reflection layer RF1 and the second reflection layer RF2 do not contact each other. The second reflection layer RF2, the connection electrode 112, and the first contact electrode CTE1 may completely overlap each other in the thickness direction.

Referring to a modification shown in FIG. 7B, the second reflection layer RF2 and the connection electrode 112 may overlap the first contact electrode CTE1 in the thickness direction, the second reflection layer RF2 and the connection electrode 112 may be formed to have a same width as each other, and width W-112 of each of the second reflection layer RF2 and of the connection electrode 112 may be smaller than a width W-C1 of the first contact electrode CTE1.

Referring to FIG. 7C, the first insulating layer INS1 may be disposed to cover side surfaces of the first element rod LD1 and the second element rod LD2.

Referring to FIGS. 7D and 7E, only one insulating layer may be disposed between a reflection layer RF1 and the element rod LD. As shown in FIG. 7D, the second insulating layer INS2 may be omitted and the first insulating layer INS1 may cover side surfaces of the first element rod LD1 but does not cover side surfaces of second element rod LD2. As shown in FIG. 7E, the first insulating layer INS1 may be omitted and the second insulating layer INS2 may be disposed to cover side surfaces of the first element rod LD1 and the second element rod LD2.

Referring to FIG. 7F, one end of the reflection layer RF1 may be formed to become thinner (i.e., become tapered) toward the element insulating layer CINS0. By including this feature of reflection layer RF1, it may be possible to prevent a short circuit that may occur later with a common electrode disposed on the second contact electrode CTE2.

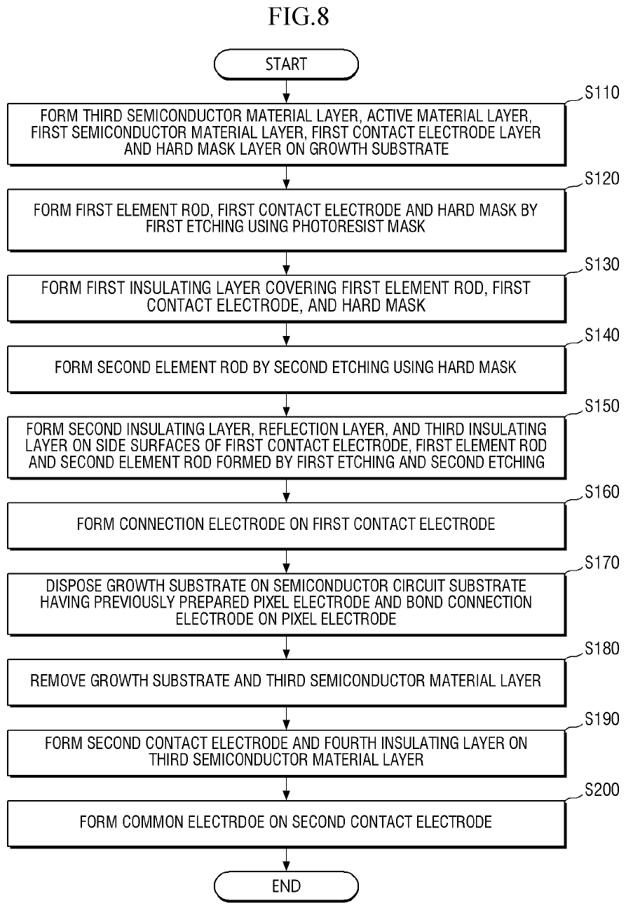

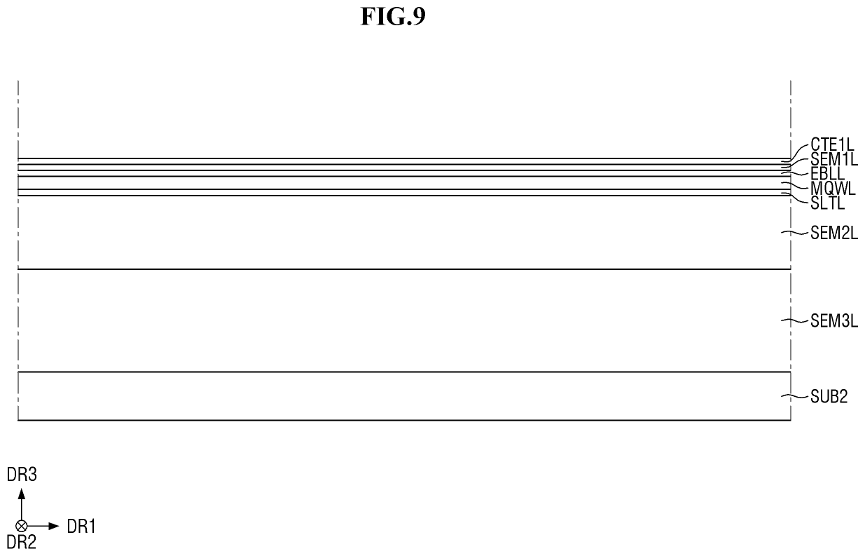

FIG. 8 is a flowchart illustrating a method of manufacturing a display device according to an embodiment. FIGS. 9 to 27 are schematic cross-sectional views illustrating the method of manufacturing a display device according to an embodiment.

FIGS. 9 to 27 are schematic cross-sectional views of structures according to the formation order of each layer of the display panel (100 in FIG. 5). In FIGS. 9 to 27, the forming and bonding processes of the light emitting element may be illustrated, and these may substantially correspond to the schematic cross-sectional view of FIG. 5.

Referring to FIG. 9, multiple semiconductor material layers SEM3L, SEM2L, SLTL, MQWL, EBLL, and SEM1L and a first contact electrode layer CTE1L may be formed on a growth substrate SUB2. (S110 of FIG. 8) First, the growth substrate SUB2 may be prepared. The growth substrate SUB2 may be a sapphire substrate (Al₂O₃) or a transparent silicon wafer containing silicon. However, the disclosure may not be limited thereto, and in one embodiment, a case where the growth substrate SUB2 may be a sapphire substrate will be described as an example.

The semiconductor material layers SEM3L, SEM2L, SLTL, MQWL, EBLL, and SEM1L may be formed on the growth substrate SUB2. The semiconductor material layers grown by an epitaxial technique may be formed by growing seed crystals. Here, the semiconductor material layers may be formed by electron beam deposition, physical vapor deposition (PVD), chemical vapor deposition (CVD), plasma laser deposition (PLD), dual-type thermal evaporation, sputtering, or metal organic chemical vapor deposition (MOCVD). Preferably, the semiconductor material layers may be formed by MOCVD, but embodiments of the specification may not be limited thereto.

A precursor material for forming the semiconductor material layers may not be particularly limited within a range of materials that can be generally selected to form a target material. For example, the precursor material may be a metal precursor including an alkyl group such as a methyl group or an ethyl group. For example, the precursor material may be, but is not limited to, a compound such as trimethyl gallium (Ga(CH₃)₃), trimethyl aluminum (Al(CH₃)₃), or triethyl phosphate (C₂H₅)₃PO₄.

Specifically, a third semiconductor material layer SEM3L may be formed on the growth substrate SUB2. In FIG. 9, it is illustrated that one third semiconductor material layer SEM3L may be stacked, but the disclosure may not be limited thereto, and multiple layers may instead be formed. The third semiconductor material layer SEM3L may be disposed to reduce a difference in lattice constant between a second semiconductor material layer SEM2L and the growth substrate SUB2. For example, the third semiconductor material layer SEM3L may include an undoped semiconductor and may be a material not doped with an n-type or a p-type dopant. In an embodiment, the third semiconductor material layer SEM3L may be, but may not be limited to, at least any one of undoped InAlGaN, GaN, AlGaN, InGaN, AlN, and InN.

The second semiconductor material layer SEM2L, a superlattice material layer SLTL, an active material layer MQWL, an electron blocking material layer EBLL, and a first semiconductor material layer SEM1L may be sequentially formed on the third semiconductor material layer SEM3L using the above-described technique.

Subsequently, a first contact electrode layer CTE1L may be deposited on the semiconductor material layers SEM3L, SEM2L, SLTL, MQWL, EBLL, and SEM1L. The first contact electrode layer CTE1L may include at least any one of gold (Au), copper (Cu), tin (Sn), silver (Ag), aluminum (Al), and titanium (Ti).

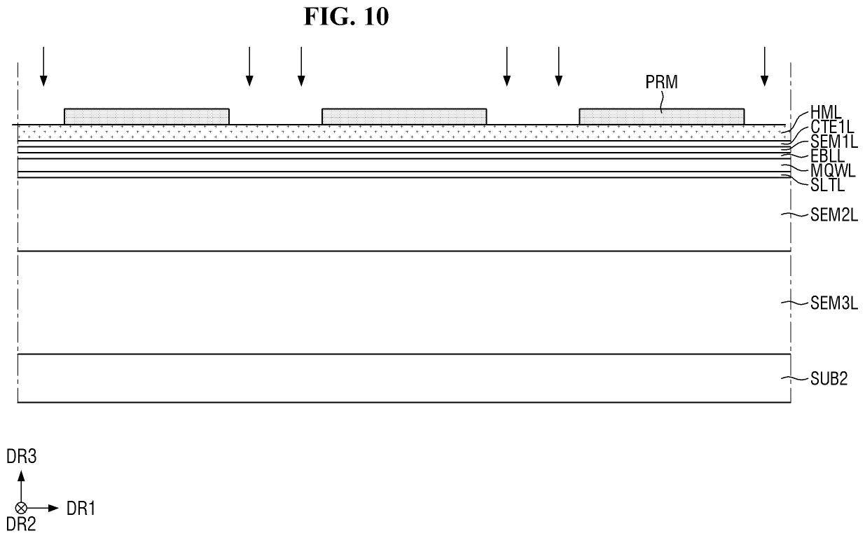

As illustrated in FIGS. 10 to 12, the first element rod LD1 may be etched using a double mask of a hard mask HM and a photoresist mask PRM. Specifically, a hard mask material layer HML may be formed on the first contact electrode layer CTE1L. The hard mask material layer HML may be formed of silicon oxide (SiOₓ). The hard mask HM formed accordingly may be also formed of silicon oxide (SiOₓ). A patterned photoresist mask PRM may be formed on the hard mask material layer HML. Photoresist may be a photosensitive material and may be organically dissolved with resin and photoresist. Accordingly, the photoresist mask PRM may be also formed of a photosensitive material.

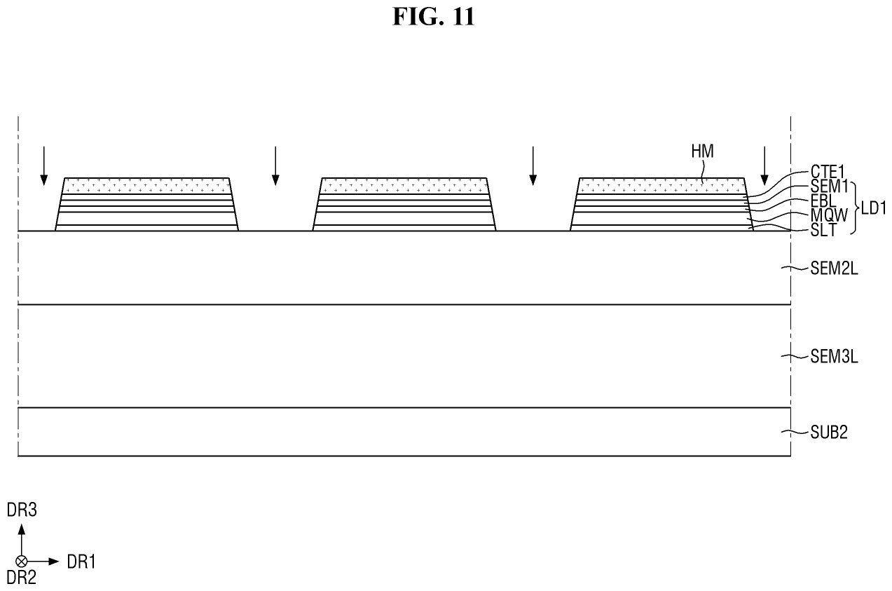

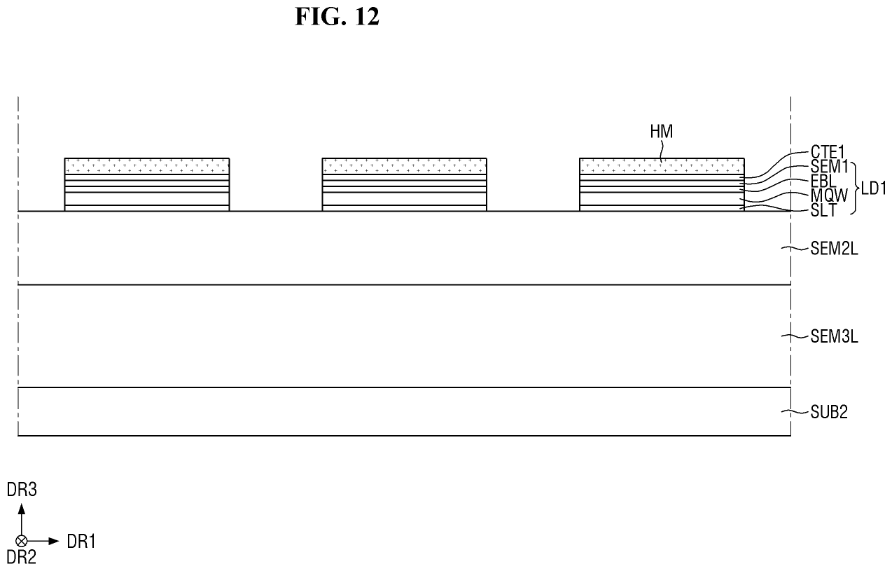

The hard mask material layer HML may be patterned through a dry etching process using the patterned photoresist mask PRM as a mask as illustrated in FIG. 10 to produce hard mask HM of FIG. 11. An upper portion of the first contact electrode CTE1 in a region that does not overlap the photoresist mask PRM patterned by the dry etching process may be exposed. The patterned photoresist mask PRM may be removed by ashing. Thereafter and as shown in FIG. 11, the first contact electrode CTE1, the first semiconductor material layer SEM1L, the electron blocking material layer EBLL, the active material layer MQWL, and the superlattice material layer SLTL may be etched using the hard mask HM as an etch mask and a first element rod LD1 may be formed (S120 of FIG. 8). During dry etching, since the process time increases and the plasma exposure time of the semiconductor material layer increases as the etching depth increases, damage to the active layer may increase. Therefore, in one embodiment, during dry etching, the second semiconductor layer SEM2L and the third semiconductor layer SEM3L may not be etched in the same etch step as when the first contact electrode CTE1, the first semiconductor material layer SEM1L, the electron blocking material layer EBLL, the active material layer MQWL, and the superlattice material layer SLTL are etched. Instead only the first semiconductor material layer SEM1L, the electron blocking material layer EBLL, the active material layer MQWL, and the superlattice material layer SLTL which correspond to about ⅓ of the entire semiconductor material layer may be etched to produce the structure of FIG. 12 in the first etching process.

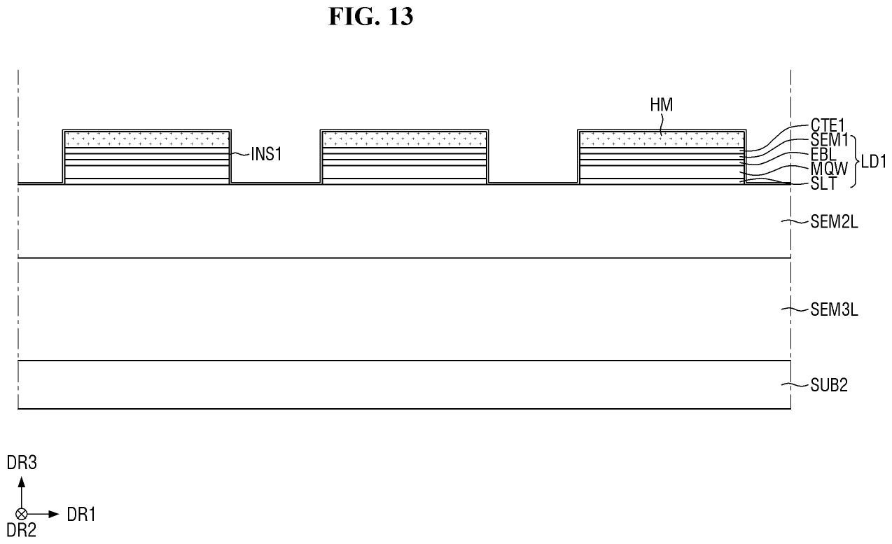

Referring to FIG. 13, a first insulating layer INS1 may be formed on side surfaces of the first element rod LD1 and on top surfaces of the second semiconductor material layer SEM2L (S130 of FIG. 8). The first insulating layer INS1 may be formed as a ZAZ (ZrO₂/Al₂O₃/ZrO₂) composite stack structure, but may not be limited thereto.

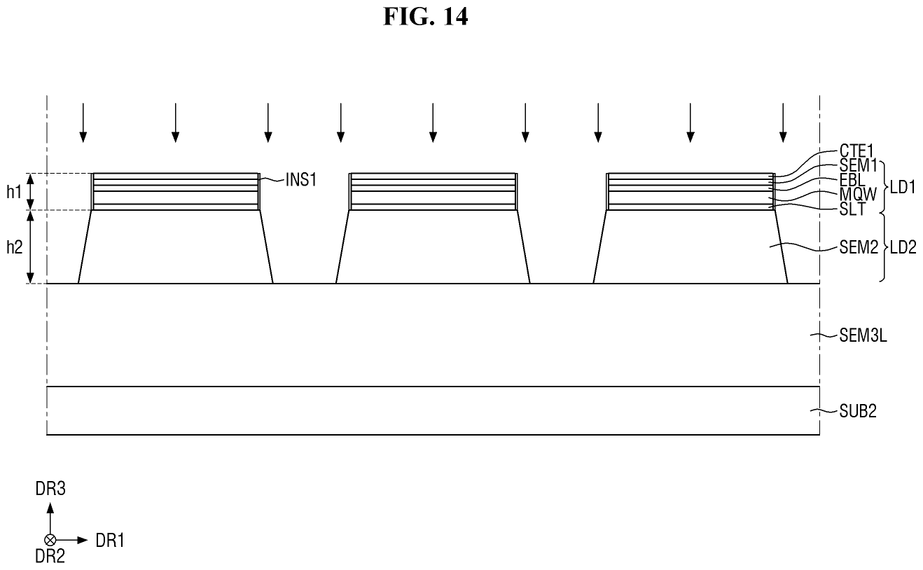

Referring to FIG. 14, the second element rod LD2 may be formed by etching the second semiconductor material layer SEM2L (S140 of FIG. 8) in a second etching process. Etching may be performed until the first contact electrode CTE1 may be exposed by etching the first insulating layer INS1 and the hard mask HM on the first element rod LD1. In case that the etching process may be completed, the height h2 of the second element rod LD2 may be about twice as the height h1 of the first element rod LD1.

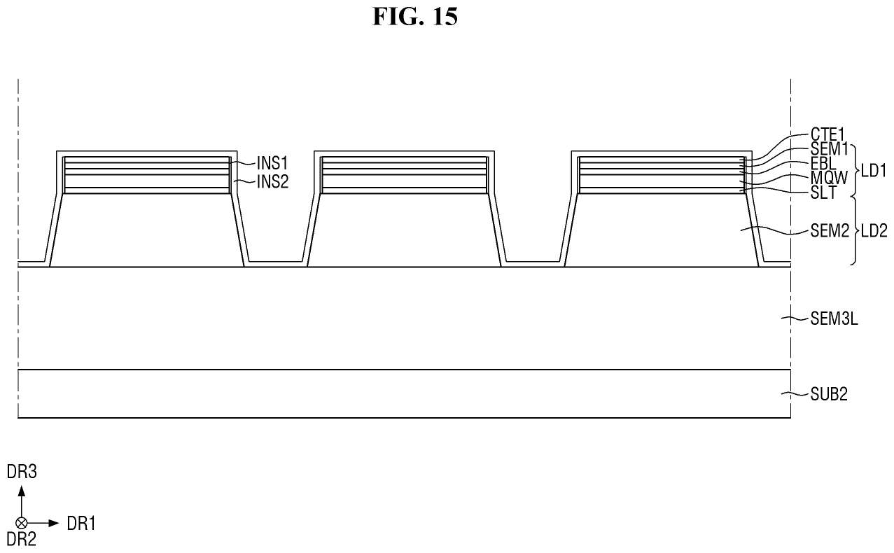

Referring to FIG. 15, a second insulating layer INS2 may be formed on the top and side surfaces of the first element rod LD1, the side surfaces of the second element rod LD2, and on the third semiconductor material layer SEM3L (S150 of FIG. 8). The second insulating layer INS2 may be made of an inorganic layer such as a silicon oxide layer (SiO₂), an aluminum oxide layer (Al₂O₃), a hafnium oxide layer (HfOₓ), or a combination thereof.

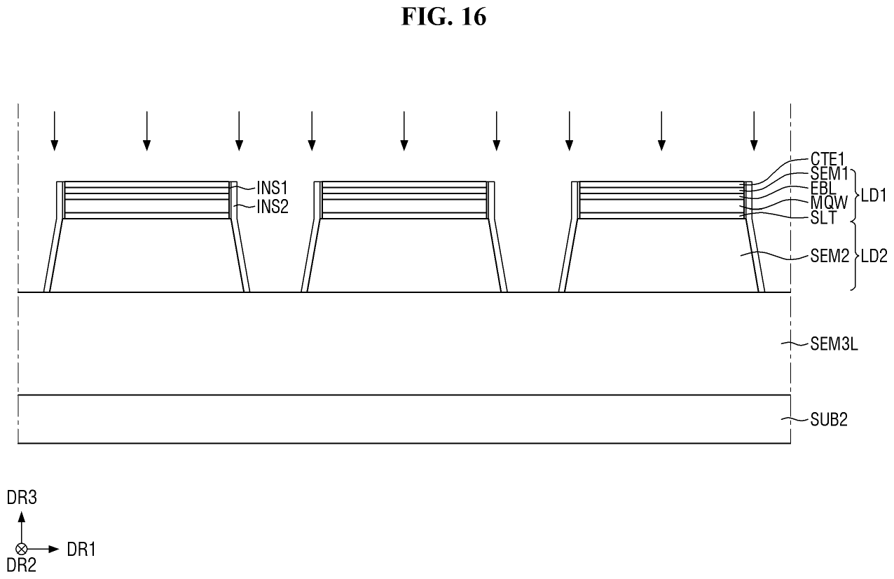

Referring to FIG. 16, portions of the second insulating layer INS2 disposed on the upper surface of the first element rod LD1 and on the third semiconductor material layer SEM3L may be removed. Accordingly, the first contact electrode CTE1 may be exposed on the upper surface of the first element rod LD1.

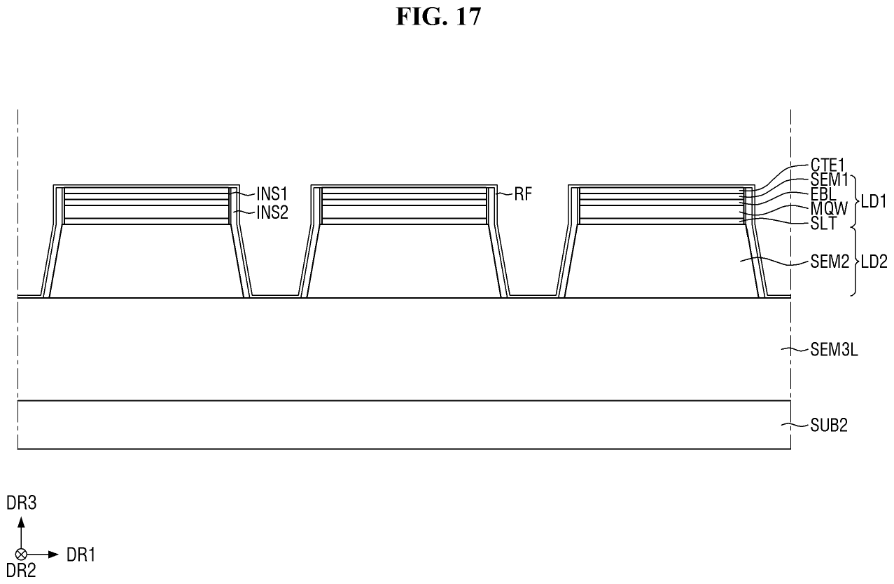

Referring to FIG. 17, a reflection layer RF may be deposited to cover the light emitting element LE. The reflection layer RF may be formed on the upper surface of the first contact electrode CTE1 of the upper surface of the light emitting element LE and on the side surfaces of the first element rod LD1 and the second element rod LD2 on the second insulating layer INS2. In an embodiment, the reflection layer RF may not be formed on a third semiconductor layer SEM3L on which the second element rod LD2 may not be disposed.

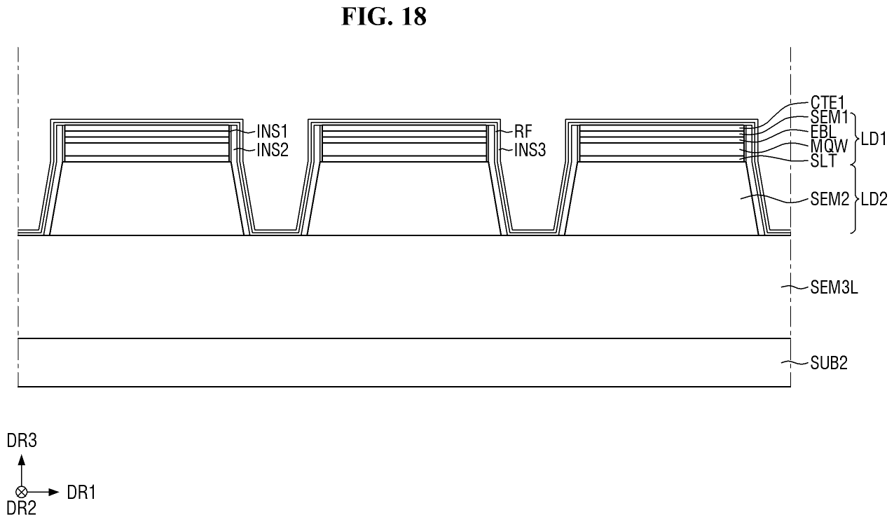

Referring to FIG. 18, a third insulating layer INS3 may be formed on the reflection layer RF (S150 of FIG. 8). The third insulating layer INS3 may be formed of an inorganic layer such as a silicon oxide layer (SiO₂) layer, an aluminum oxide layer (Al₂O₃) layer, a hafnium oxide layer (HfOₓ) layer, or a combination thereof but may not be limited thereto.

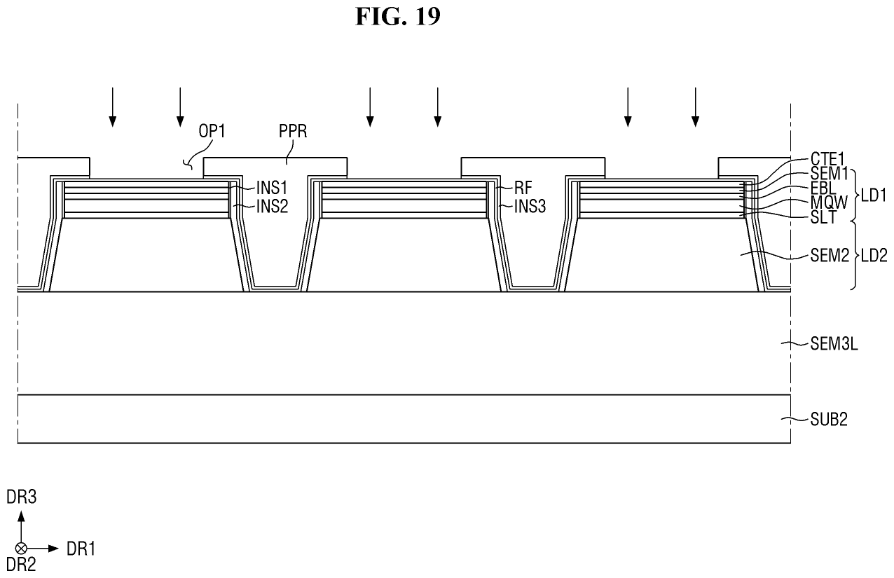

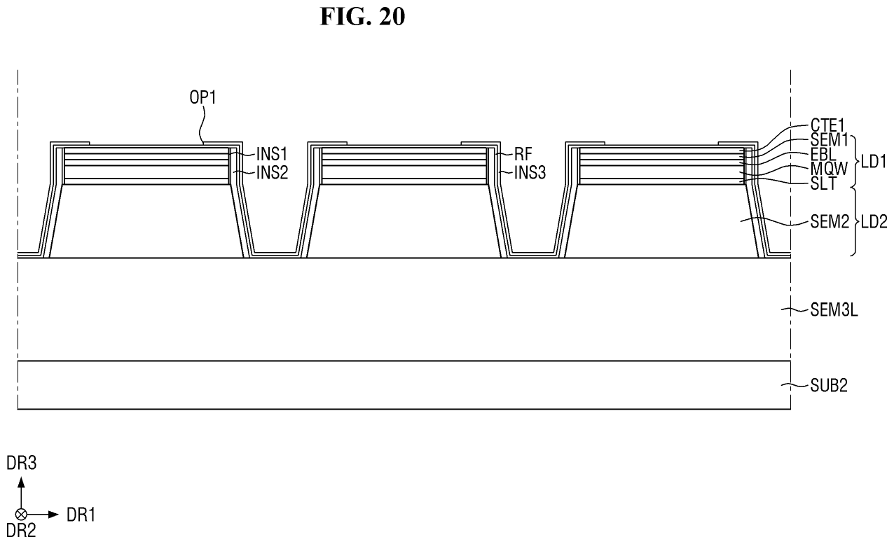

Referring to FIGS. 19 and 20, a first opening OP1 may be formed in the third insulating layer INS3 of the upper surface of the first element rod LD1 by using a positive photoresist mask PPR. The first opening OP1 may be formed by removing the third insulating layer INS3 in the portion where the positive photomask PPR may not be formed. The reflection layer RF may be exposed through the first opening OP1. An area of the connection electrode 112 may be defined by the first opening OP1.

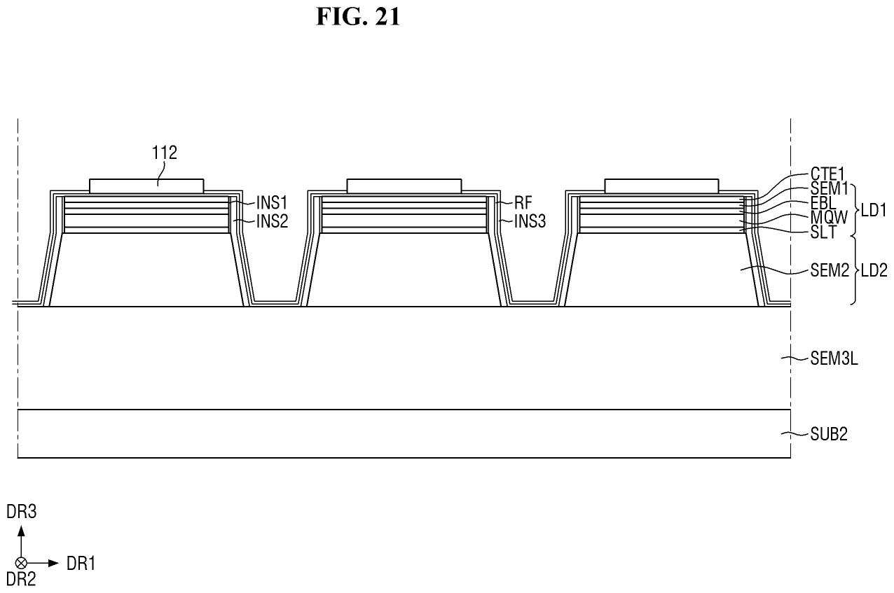

Referring to FIG. 21, a connection electrode 112 may be formed in the first opening OP1 (S160 of FIG. 8). Specifically, a negative photoresist mask may be formed in a region that does not overlap the first opening OP1. A connection electrode 112 may be formed on the first opening OP1 by using the negative photoresist mask. The connection electrode 112 may be in contact with the first contact electrode CTE1. Thereafter, the negative photoresist mask may be removed.

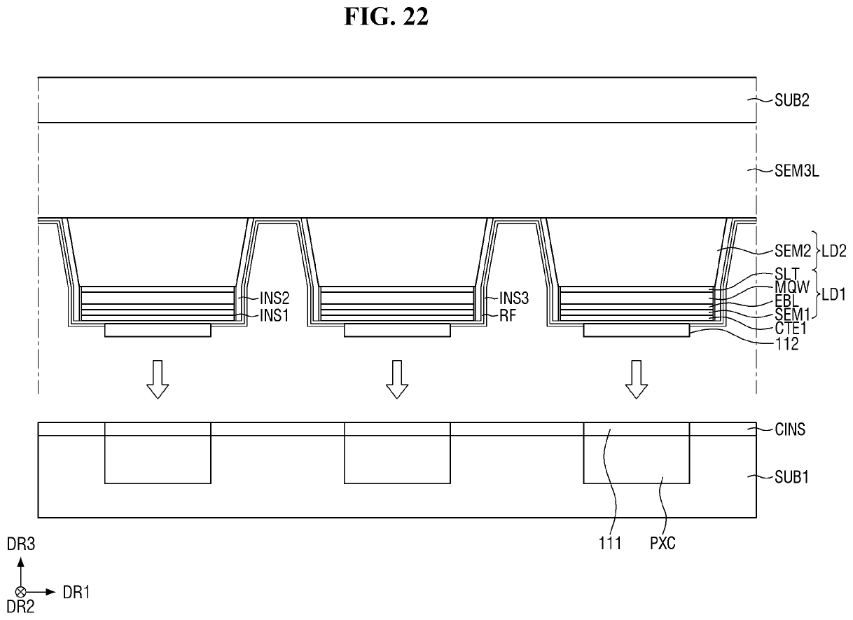

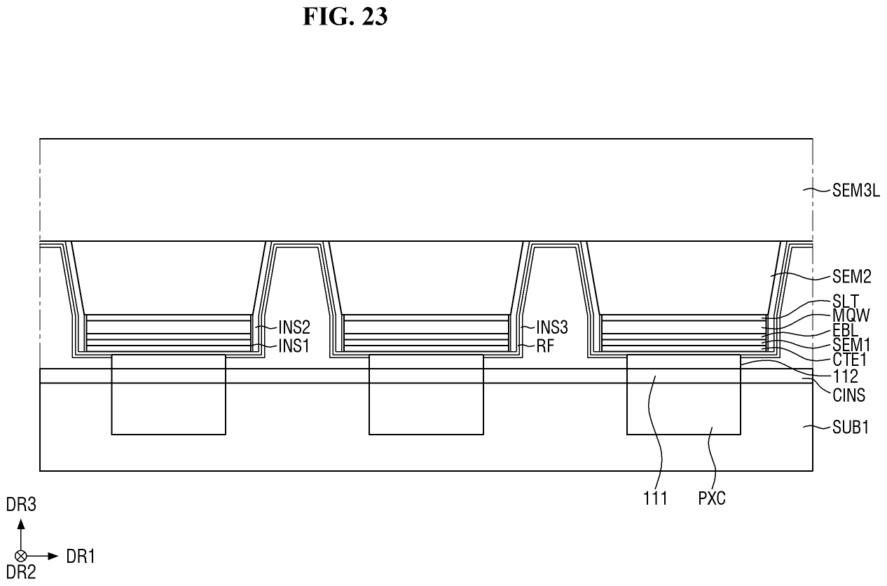

Referring to FIGS. 22 and 23, a pixel electrode 111 of a semiconductor circuit substrate SUB1 and a light emitting element LE of a growth substrate SUB2 may be bonded by the connection electrode 112 (S170 of FIG. 8), and the growth substrate SUB2 may be removed (S180 of FIG. 8). The connection electrode 112 may serve as a bonding metal for bonding the pixel electrodes 111 and the light emitting elements LE.

Specifically, the pixel electrode 111 of the semiconductor circuit substrate SUB1 may be brought into contact with the connection electrode 112 of the light emitting element LE of the growth substrate SUB2. The pixel electrodes 111 and the light emitting elements LE may be bonded by melting and bonding the connection electrodes 112 at a temperature. For example, the connection electrode 112 may be disposed between the pixel electrode 111 of the semiconductor circuit substrate SUB1 and the light emitting element LE of the growth substrate SUB2 to serve as a bonding metal layer that bonds the pixel electrodes 111 and the light emitting elements LE (S170 of FIG. 8).

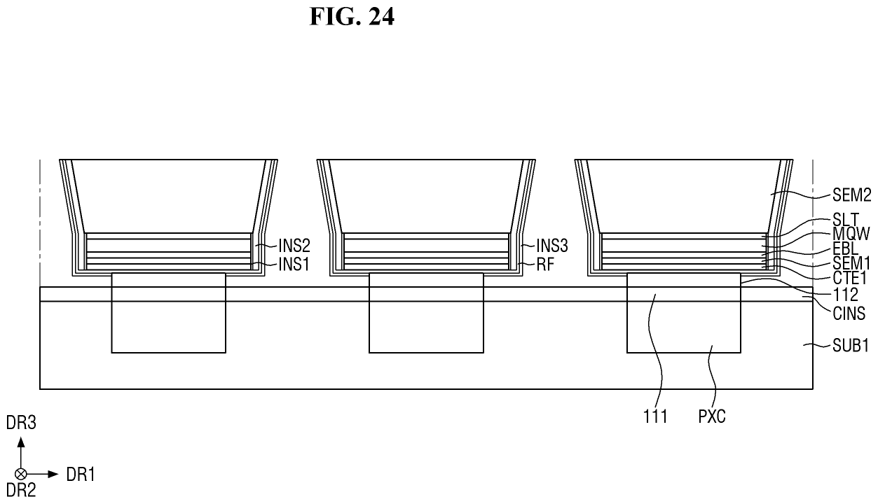

Thereafter as illustrated in FIG. 23, the growth substrate SUB2 may be removed through a polishing process such as a chemical mechanical polishing (CMP) process and/or an etching process (S180 of FIG. 8). As illustrated in FIG. 24, the third semiconductor material layer SEM3L on the light emitting elements LE may be removed through a polishing process such as a CMP process (S180 of FIG. 8).

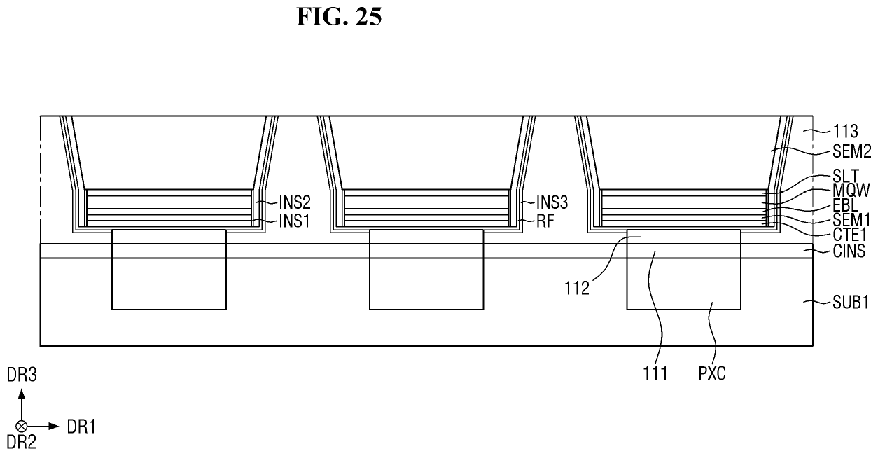

As illustrated in FIG. 25, a planarization layer 113 may be formed between the light emitting elements LE. The planarization layer 113 may fix the light emitting elements LE. The planarization layer 113 may be formed by coating an organic material between the light emitting elements LE. The organic material may be an acrylic resin, an epoxy resin, a phenolic resin, a polyamide resin, a polyimide resin, the like, or a combination thereof.

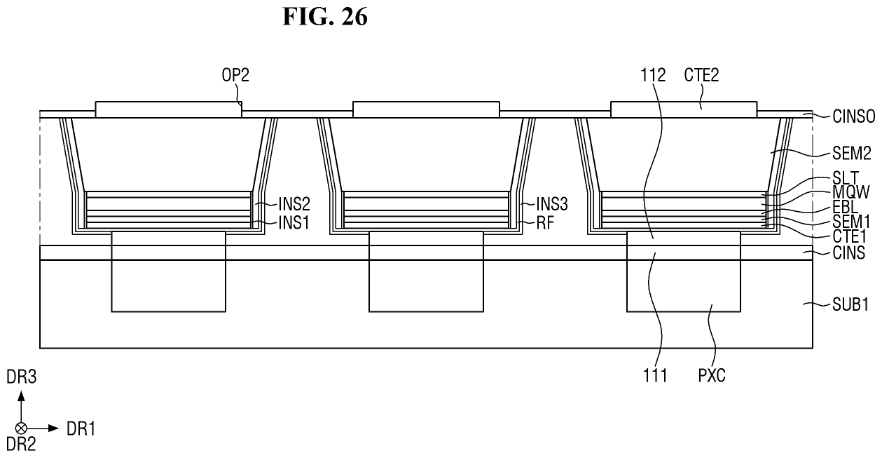

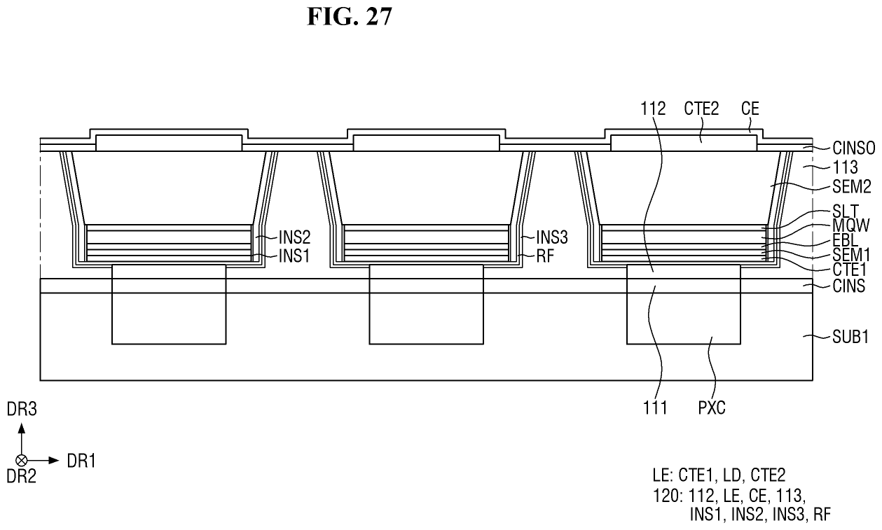

As illustrated in FIG. 26, an element insulating layer CINS0 having a second opening OP2 and a second contact electrode CTE2 disposed in the second opening OP2 may be formed (S190 of FIG. 8). Thereafter, as illustrated in FIG. 27, the common electrode CE may be disposed on the second contact electrode CTE2 and the element insulating layer CINS0 (S200 of FIG. 8). The common electrode CE and the second contact electrodes CTE2 of the light emitting elements LE may be electrically connected.

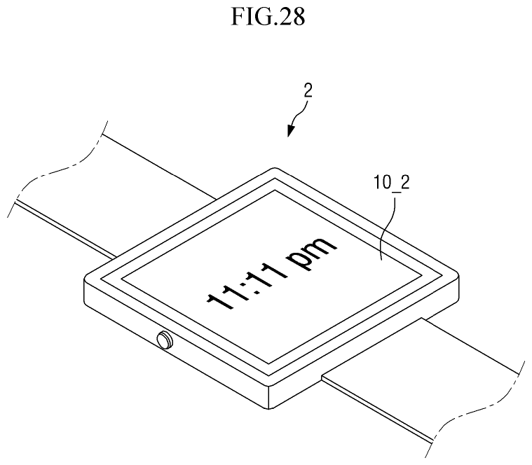

FIG. 28 is a perspective view of a smart device including a display device according to the embodiment of FIG. 1. Referring to FIG. 28, a display device 10_2 according to the embodiment of FIG. 1 may be applicable to a smartwatch 2, which may be a type of smart device. The smartwatch 2 may generally have a rectangular shape except for a wristband, in a plan view. For example, the planar shape of the display portion of the smart watch 2 may conform to the planar shape of the display device 10_2.

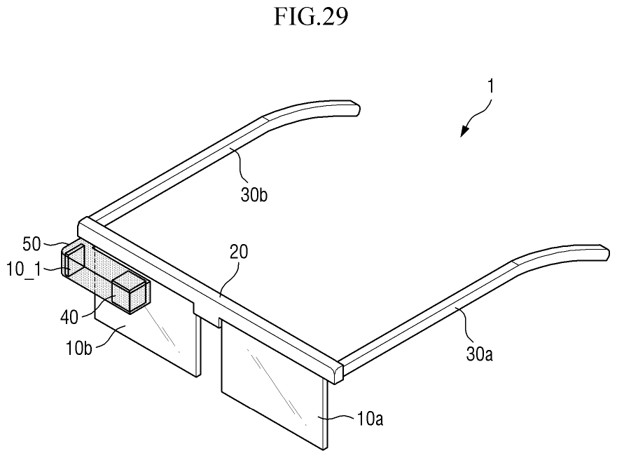

FIG. 29 is a perspective view of a virtual reality (VR) device a display device according to an embodiment of the disclosure. FIG. 29 illustrates a VR device 1, to which a display device 10_1 according to the embodiment of FIG. 1 may be applied.

Referring to FIG. 29, the VR device 1 may be an eyeglass-type device. The VR device 1 may include the display device 10_1, a left-eye lens 10a, a right-eye lens 10b, a support frame 20, eyeglass temples 30a and 30b, a reflective member 40, and a display device storage compartment 50.

FIG. 29 illustrates the VR device 1 including the eyeglass temples 30a and 30b, but the VR device 1 may also be applicable to a head-mounted display (HMD) including a headband that can be worn on the head, instead of the eyeglass temples 30a and 30b. For example, the VR device 1 may not be particularly limited to that illustrated in FIG. 29 and may be applicable to various types of electronic devices.

The display device storage compartment 50 may include the display device 10_1 and the reflective member 40. An image displayed by the display device 101 may be reflected by the reflective member 40 and may thus be provided to the right eye of a user through the right-eye lens 10b. Thus, the user may view a VR image, displayed by the display device 10_1, through his or her right eye.

FIG. 29 illustrates that the display device storage compartment 50 may be disposed at the right end of the support frame 20, but the disclosure may not be limited thereto. In an embodiment, the display device storage compartment 50 may be disposed at the left end of the support frame 20, in which case, an image displayed by the display device 101 may be reflected by the reflective member 40 and may thus be provided to the left eye of the user through the left-eye lens 10a. In yet an embodiment, two display device storage compartments 50 may be disposed at both the left and right ends of the support frame 20, in which case, the user may view a VR image, displayed by the display device 10_1, through both his or her left and right eyes.

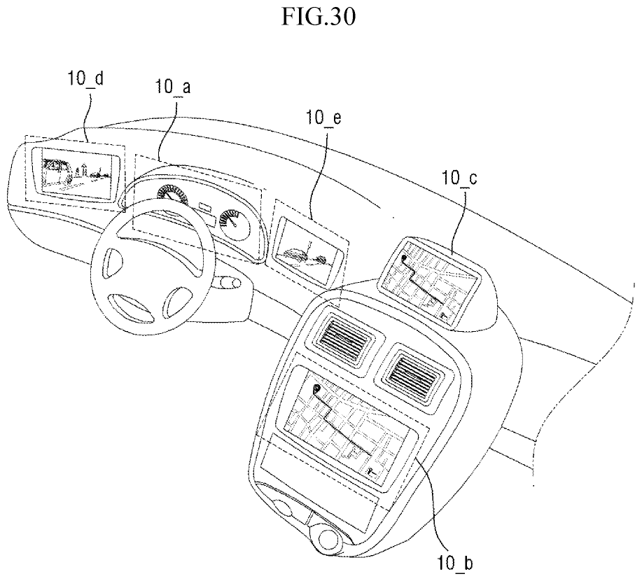

FIG. 30 is a perspective view of a dashboard and a center console of an automobile including display devices according to an embodiment of the disclosure. FIG. 30 illustrates an automobile, to which display devices 10_a, 10_b, 10_c, 10_d, and 10_e according to the embodiment of FIG. 1 are applied.

Referring to FIG. 30, the display devices 10_a, 10_b, and 10_c may be applicable to the dashboard or center console of an automobile or to a center information display (CID) in the dashboard of an automobile. The display devices 10_d and 10_e may be applicable to room mirror displays that can replace the rear view mirrors of an automobile.

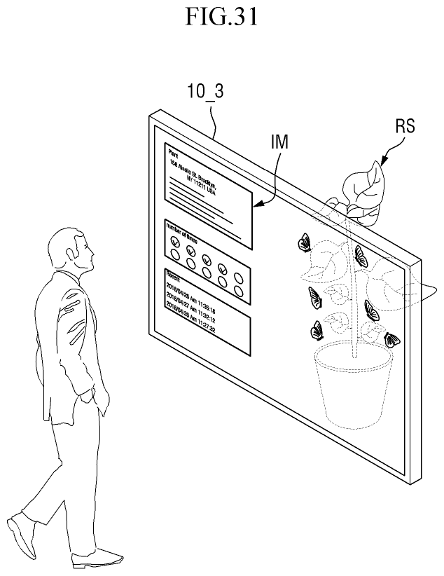

FIG. 31 is a transparent display device including a display device according to an embodiment of the disclosure. Referring to FIG. 31, a display device 10_3 according to the embodiment of FIG. 1 may be applicable to a transparent display device. The transparent display device may display an image IM and at a same time, transmit light therethrough. Thus, a user at the front of the transparent display device may view not only the image IM on the display device 103, but also an object RS or the background at the rear of the transparent display device. In a case where the display device 10_3 may be applied to the transparent display device, a substrate SUB of the display device 10_3 may include light-transmitting parts capable of transmitting light therethrough or may be formed of a material capable of transmitting light therethrough.

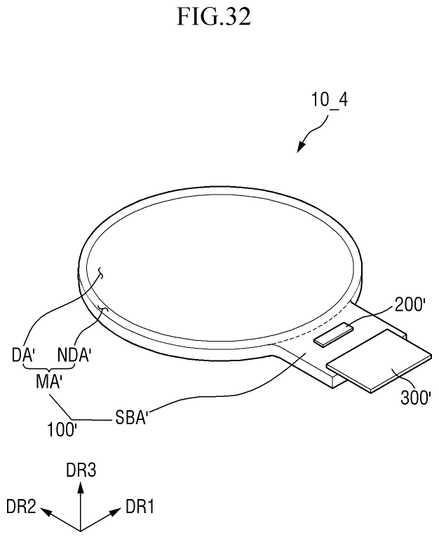

FIG. 32 is a perspective view of a display device according to an embodiment of the disclosure. The embodiment of FIG. 32 differs from the embodiment of FIG. 1 only in that a display area DA and a main area MA of a display panel 100′ have a circular shape in a plan view, and thus, a detailed description thereof will be omitted.

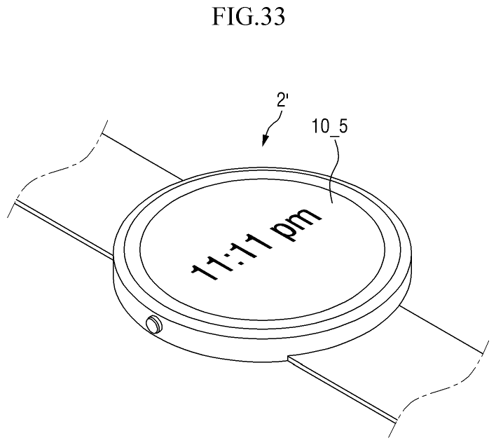

FIG. 33 is a perspective view of a smart device including the display device of FIG. 32. Referring to FIG. 33, a smartwatch 2′ generally has a circular shape except for a wristband. For example, the planar shape of display portion of the smartwatch may conform to the planar shape of a display device 10_5.

However, the aspects of the disclosure may not be restricted to the one set forth herein. The above and other aspects of the disclosure will become more apparent to one of daily skill in the art to which the disclosure pertains by referencing the claims, with functional equivalents thereof to be included therein.

What is claimed is:

1. A light emitting element comprising:
an element rod including a first semiconductor layer, an active layer, and a second semiconductor layer;
first and second contact electrodes respectively disposed on a first end surface and a second end surface facing the first end surface of the element rod;
a reflection layer surrounding the first contact electrode and the element rod;
an inner insulating layer disposed inside the reflection layer and surrounding the first contact electrode and the element rod; and
an outer insulating layer disposed external to the reflection layer and surrounding the first contact electrode and the element rod,
wherein a first inclination of side surfaces of the first semiconductor layer and the active layer and a second inclination of a side surface of the second semiconductor layer are different.

2. The light emitting element of claim 1, wherein
the second inclination is an angle between a reference surface and a side surface of the second semiconductor layer,
the first inclination is an angle between the reference surface and side surfaces of the first semiconductor layer and the active layer, and
the reference surface is a surface parallel to contact surfaces of the second contact electrode and the second semiconductor layer.

3. The light emitting element of claim 2, wherein the second inclination is smaller than the first inclination.

4. The light emitting element of claim 1, wherein a width of the second semiconductor layer is wider towards the second contact electrode.

5. The light emitting element of claim 4, further comprising:
a common electrode disposed on the second contact electrode.

6. The light emitting element of claim 1, wherein
the inner insulating layer includes a first insulating layer surrounding a side surface of the first contact electrode and the side surfaces of the first semiconductor layer and the active layer, and a second insulating layer surrounding a side surface of the first insulating layer and the side surface of the second semiconductor layer,
the outer insulating layer includes a third insulating layer surrounding a side surface and a first surface of the reflection layer,
the third insulating layer defines a first opening exposing the first surface of the reflection layer, and
the light emitting element further includes a connection electrode disposed in the first opening.

7. The light emitting element of claim 1, wherein the reflection layer comprises:
a first reflection layer disposed on the second insulating layer, the first reflection layer surrounding the side surfaces of the first semiconductor layer, the active layer and the second semiconductor layer; and
a second reflection layer disposed on the first contact electrode, the second reflection layer covering a first surface of the first semiconductor layer.

8. The light emitting element of claim 7, wherein the second reflection layer extends from the first reflection layer.

9. The light emitting element of claim 7, wherein
the second reflection layer is spaced apart from the first reflection layer, and
the outer insulating layer is further disposed between the second reflection layer and the first reflection layer.

10. The light emitting element of claim 1, further comprising:
a fourth insulating layer disposed on the second semiconductor layer, the fourth insulating layer defining a second opening exposing the second semiconductor layer,
wherein the second contact electrode is disposed in the second opening.

11. A display device comprising:
a semiconductor circuit substrate including a pixel circuit portion;
a light emitting element disposed on the pixel circuit portion;
a connection electrode disposed between the light emitting element and the pixel circuit portion; and
a common electrode disposed on the light emitting element, wherein
the light emitting element comprises:
an element rod including a first semiconductor layer, an active layer, and a second semiconductor layer;
first and second contact electrodes respectively disposed on a first end surface and on a second and opposite end surface of the element rod,
a first insulating layer surrounding side surfaces of the first contact electrode, the first semiconductor layer and the active layer;
a second insulating layer surrounding a side surface of the first insulating layer and a side surface of the second semiconductor layer;
a reflection layer surrounding a side surface of the second insulating layer and a first surface of the first contact electrode; and
a third insulating layer surrounding a side surface and a first surface of the reflection layer, and
a first inclination of the side surfaces of the first semiconductor layer and the active layer and a second inclination of the side surface of the second semiconductor layer are different.

12. The display device of claim 11, wherein
the second inclination is an angle between a reference surface and the side surface of the second semiconductor layer,
the first inclination is an angle between the reference surface and the side surfaces of the first semiconductor layer and the active layer,
the reference surface is parallel to a contact surface of the second contact electrode and a contact surface of the second semiconductor layer, and
the second inclination is smaller than the first inclination.

13. The display device of claim 11, wherein a width of the second semiconductor layer is wider towards a second contact electrode.

14. The display device of claim 11, wherein
the third insulating layer includes a first opening exposing the first surface of the reflection layer,
the connection electrode is disposed in the first opening,
the light emitting element further includes a fourth insulating layer disposed between the second semiconductor layer and the common electrode, the fourth insulating layer defining a second opening exposing the second semiconductor layer, and
the second contact electrode is disposed in the second opening.

15. The display device of claim 11, wherein the reflection layer comprises:
a first reflection layer disposed on the second insulating layer, the first reflection layer surrounding the side surfaces of the first semiconductor layer, the active layer and the second semiconductor layer; and
a second reflection layer disposed on the first contact layer, the second reflection layer overlapping a first surface of the first semiconductor layer.

16. The display device of claim 15, wherein the second reflection layer extends from the first reflection layer.

17. The device of claim 15, wherein
the second reflection layer is spaced apart from the first reflection layer, and
the third insulating layer is disposed between the second reflection layer and the first reflection layer.

18. The display device of claim 11, further including:
a fourth insulating layer disposed between the second semiconductor layer and the common electrode, the fourth insulating layer defining a second opening exposing the second semiconductor layer,
wherein the second contact electrode is disposed in the second opening.

19. A method of fabricating a display device, the method comprising:
forming a first semiconductor material layer, a second semiconductor material layer, an active material layer, a third semiconductor material layer, a first contact electrode layer, and a hard mask layer on a growth substrate;
forming a first element rod, a first contact electrode, and a hard mask by etching the active material layer, the third semiconductor material layer, the first contact electrode layer, and the hard mask layer using a photoresist mask in a first etching process;
forming a first insulating layer covering the first element rod, the first contact electrode, and the hard mask;
forming a second element rod by etching the second semiconductor material layer using the hard mask in a second etching process;
forming a second insulating layer, a reflection layer, and a third insulating layer on side surfaces of the first contact electrode, the first element rod, and the second element rod formed by the first etching process and the second etching process;
forming a connection electrode on the first contact electrode;
disposing the growth substrate on a semiconductor circuit substrate having a pixel electrode formed thereon;
bonding the connection electrode to the pixel electrode;
removing the growth substrate and the first semiconductor material layer;
forming a second contact electrode and a fourth insulating layer on the second semiconductor material layer; and
forming a common electrode on the second contact electrode,
wherein a first inclination of side surfaces of the first semiconductor layer and the active layer and a second inclination of a side surface of the second semiconductor layer are different.

20. The method of claim 19, wherein the forming of the second insulating layer, the reflection layer, and the third insulating layer comprises:
forming the second insulating layer surrounding the side surfaces of the first contact electrode, the first element rod and the second element rod formed by the first etching process and the second etching process;
forming the reflection layer on the second insulating layer, the reflection layer covering the side surfaces of the first contact electrode, the first element rod, and the second element rod and a first surface of the first contact electrode;
forming the third insulating layer on the reflection layer, the third insulating layer being disposed on the side surfaces of the first contact electrode, the first element rod, and the second element rod and the first surface of the first contact electrode, the third insulating layer having an opening; and
forming the connection electrode on a portion of the first contact electrode exposed by the opening.
